(19) United States
(12) Patent Application Publication
(10) Pub. No.: US 2008/0309232 A1
(43) Pub. Date: Dec. 18, 2008

(54) DISPLAY APPARATUS AND METHOD OF MANUFACTURING THE SAME

(75) Inventor: Kazuto YAMAMOTO, Nishitama-gun (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/137,021

(22) Filed: Jun. 11, 2008

(30) Foreign Application Priority Data
Jun. 12, 2007 (JP) 2007-155129

(51) Int. Cl. H01J 1/62

(52) U.S. Cl. 313/505

(57) ABSTRACT

A display apparatus includes a light-emitting function layer, a first electrode, a second electrode, a flat reflecting layer, and a flat insulating film. The light-emitting function layer includes at least one layer. The second electrode is provided to face the first electrode through the light-emitting function layer. The flat insulating film is provided between the flat reflecting layer and the first electrode. The first electrode, second electrode, and flat insulating film have a transmission characteristic with respect to at least light having a wavelength that is in part of a wavelength range of light emitted from the light-emitting function layer. The flat reflecting layer has a reflection characteristic with respect to at least the light having the wavelength that is in part of the wavelength range of the light emitted from the light-emitting function layer.

### CROSS-REFERENCE TO RELATED APPLICATIONS

This application is based upon and claims the benefit of priority from prior Japanese Patent Application No. 2007-155129, filed Jun. 12, 2007, the entire contents of which are incorporated herein by reference.

### BACKGROUND OF THE INVENTION

1. Field of the Invention

The present invention relates to a display apparatus and its manufacturing method and, more particularly, to a display apparatus including display pixels having light-emitting elements such as organic electroluminescence elements and a method of manufacturing the display apparatus.

2. Description of the Related Art

Recently, research and development have been vigorously carried out for the full-scale practical use and popularization of display apparatuses including light-emitting element type display panels comprising two-dimensional arrays of self-luminous elements such as organic electroluminescence elements (to be abbreviated to “organic EL elements” hereinafter) and light-emitting diodes (LEDs) as next-generation display devices following liquid crystal display apparatuses (LCDs).

Light-emitting element type display apparatuses using the active matrix driving scheme, in particular, have excellent display characteristics that they are higher in display response speed than liquid crystal display apparatuses and have no viewing angle dependence. In addition, light-emitting element type display apparatuses have a characteristic in terms of apparatus configuration that they do not need any backlight or light guide plate unlike liquid crystal display apparatuses. For this reason, light-emitting element type display apparatuses are expected to be applied to various electronic devices in the future.

As such a display apparatus based on the active matrix driving scheme, there is known an apparatus that has a pixel circuit (pixel driving circuit) for causing a light-emitting element (an organic EL, element) to emit light at a desired luminance level for each of display pixels arrayed on a display panel. As this pixel circuit, for example, a circuit comprising one or a plurality of switching elements such as thin-film transistors and an interconnection layer is known, as disclosed in Jpn. Pat. Appln. KOKAI Publication No. 8-330600.

As display panels each having a pixel circuit and a light-emitting element, which constitute each display pixel, formed on one surface side of a substrate, there are known a top emission type display panel that applies light to one surface side of a substrate in accordance with the device structure of each light-emitting element and a bottom emission type display panel that applies light to the other surface side of a substrate. As described in, for example, Jpn. Pat. Appln. KOKAI Publication No. 2005-222759, a top emission type display panel is configured such that light emitted from a light-emitting element provided on one surface side is reflected by the substrate without being transmitted and applied to one surface side, whereas a bottom emission type display panel has a light emission structure in which light emitted from a light-emitting element is transmitted through the substrate and applied to the other surface side.

In the active matrix type display panel, as described above, it is necessary to form, for each display pixel, a pixel circuit having circuit elements such as transistors and a light-emitting element such as an organic EL element on the same substrate. Each circuit element on the pixel circuit and each light-emitting element can be two-dimensionally stacked on each other on the substrate (i.e., multilayer formation). This can increase not only the pixel aperture ratio but also the degree of freedom in layout design of circuit elements as compared with a bottom emission type light emission structure in which pixel circuits (circuit elements) and light-emitting elements need to be arranged so as not to be two-dimensionally stacked.

In a display panel having such a top emission type light emission structure, an organic EL element formed in each display pixel has, for example, the following device structure. A reflecting layer, a transparent pixel electrode (e.g., an anode electrode), a luminescent layer such as an organic EL layer, and a transparent opposed electrode (e.g., a cathode electrode) are sequentially stacked on a substrate on which the respective circuit elements of each pixel circuit are formed. The light emitted by the luminescent layer is directly applied to the visual field side via the opposed electrode. In addition, the light applied in the direction of the substrate is reflected by the reflecting layer and is then applied to the visual field side via the luminescent layer and the opposed electrode. With this operation, desired image information is displayed.

However, in a display panel having a top emission type light emission structure like that described above, the light emitted by the luminescent layer is directly applied to the visual field side via the opposed electrode, and the light applied in the direction of the substrate is reflected by the reflecting layer and is applied to the visual field side via the luminescent layer and the opposed electrode. This causes an optical path difference corresponding to the film thickness between the applied light beams, which then causes chromaticity shifts and emission luminance (emission intensity) fluctuations, resulting in a deterioration in display characteristic such as image blurring. The present inventor has inspected and found that the above characteristic deterioration is noticeable when a polymer-based organic EL element is used as a light-emitting element. Note that concrete characteristic deteriorations of a display panel will be described in detail in the following description of the embodiments of the present invention.

### BRIEF SUMMARY OF THE INVENTION

It is an object of the present invention to provide a display apparatus that has excellent display characteristics without any image blurring or the like by suppressing chromaticity shifts and emission luminance (emission intensity) fluctuations, and a method of manufacturing the display apparatus.

A display apparatus according to the present invention comprises a light-emitting function layer including at least one layer, a first electrode that has a transmission characteristic with respect to at least light having a wavelength that is in part of a wavelength range of light emitted from the light-emitting function layer, a second electrode that is provided to face the first electrode through the light-emitting function layer and has a transmission characteristic with respect to at least the light having the wavelength that is in part of the wavelength range of the light emitted from the light-emitting function layer, a flat reflecting layer that has a reflection characteristic with respect to at least the light having the wavelength that is in part of the wavelength range of the light emitted from the light-emitting function layer, and a flat insulating film that is provided between the flat reflecting layer and the first electrode and has a transmission characteristic with respect to at least the light having the wavelength that is in part of the wavelength range of the light emitted from the light-emitting function layer.

The flat insulating film preferably has a refractive index substantially equal to that of the first electrode.

The first electrode may include a conductive oxide metal layer, and the flat insulating film may include an organic film.

The flat insulating film preferably has a refractive index of approximately 1.6, and a thickness of not less than 2,000 nm.

The light-emitting function layer preferably includes luminescent layers of different emission colors for the respective pixels, and the flat insulating film preferably has different thicknesses in accordance with the emission colors.

The apparatus may further comprise a pixel driving circuit that is connected to the first electrode and supplies an emission driving current.

The display apparatus may further comprise a pixel driving circuit that supplies an emission driving current, and a protective insulating film that covers the pixel driving circuit, and the first electrode may be connected to the pixel driving circuit through an opening portion extending through the flat insulating film and the protective insulating film.

The display apparatus may further comprise a pixel driving circuit that supplies an emission driving current, and the flat reflecting layer may be electrically connected to the pixel driving circuit and the first electrode is electrically connected to the flat reflecting layer.

The display apparatus may further comprise a pixel driving circuit that supplies an emission driving current, and a protective insulating film that covers the pixel driving circuit, and the flat reflecting layer may be connected to the pixel driving circuit through a first opening portion provided in the protective insulating film, and the first electrode may be electrically connected to the flat reflecting layer through a second opening portion provided in the flat insulating film.

The display apparatus may further comprise a pixel driving circuit that supplies an emission driving current and includes an electrode and an interconnection layer, and at least one of the electrode and the interconnection layer of the pixel driving circuit may two-dimensionally overlap the first electrode through the flat insulating film.

The light-emitting function layer may include an organic EL layer or a polymer-based organic material.

A method of manufacturing a display apparatus including a light-emitting function layer comprises steps of forming a flat reflecting layer having a reflection characteristic with respect to at least light having a wavelength that is in part of a wavelength range of light emitted from the light-emitting function layer, forming, on the flat reflecting layer, a flat insulating film that has a transmission characteristic with respect to at least the light having the wavelength that is in part of the wavelength range of the light emitted from the light-emitting function layer, forming, on the flat insulating film, a first electrode that has a transmission characteristic with respect to at least the light having the wavelength that is in part of the wavelength range of the light emitted from the light-emitting function layer, forming the light-emitting function layer on the first electrode, and forming, on the light-emitting function layer, a second electrode that has a transmission characteristic with respect to at least the light having the wavelength that is in part of the wavelength range of the light emitted from the light-emitting function layer.

A method of manufacturing a display apparatus including a light-emitting function layer comprises steps of forming a protective insulating film that has a first opening portion on a pixel driving circuit, forming, on the protective insulating film and the first opening portion, a flat reflecting layer that has a reflection characteristic with respect to at least light having a wavelength that is in part of a wavelength range of light emitted from the light-emitting function layer, forming a flat insulating film that has a second opening portion exposing a portion of the flat reflecting layer and has a transmission characteristic with respect to at least the light having the wavelength that is in part of the wavelength range of the light emitted from the light-emitting function layer covering the other portion of the flat reflecting layer, forming, on the flat insulating film and the second opening portion, a first electrode that has a transmission characteristic with respect to at least the light having the wavelength that is in part of the wavelength range of the light emitted from the light-emitting function layer, forming the light-emitting function layer on the first electrode, and forming, on the light-emitting function layer, a second electrode that has a transmission characteristic with respect to at least the light having the wavelength that is in part of the wavelength range of the light emitted from the light-emitting function layer.

The flat insulating film preferably has a refractive index substantially equal to that of the first electrode.

The flat insulating film may have a refractive index of approximately 1.6, and a thickness of not less than 2,000 nm.

The light-emitting function layer preferably includes luminescent layers of different emission colors for the respective pixels, and the flat insulating film preferably has different thicknesses in accordance with the emission colors.

The display apparatus and its manufacturing method according to the present invention can implement excellent display characteristics without any image blurring or the like by suppressing chromaticity shifts and emission luminance (emission intensity) fluctuations.

Advantages of the invention will be set forth in the description that follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic plan view showing an example of the pixel array state of a display panel applied to a display apparatus according to the present invention;

FIG. 2 is an equivalent circuit diagram showing an example of the circuit arrangement of each of display pixels (light-emitting elements and pixel driving circuits) two-dimensionally arrayed on the display panel of the display apparatus according to the present invention;

FIG. 3 is a plan layout view showing an example of a display pixel that can be applied to the display apparatus (display panel) according to the first embodiment;

FIGS. 4A and 4B are schematic sectional views each showing the A-A section of a display pixel having a plan layout according to the first embodiment;

FIG. 5 is a schematic sectional view showing the B-B section of the display pixel having the plan layout according to the first embodiment;

FIGS. 6A, 6B, 6C, and 6D are sectional views (No. 1) showing an example of a method of manufacturing the display apparatus (display panel) according to the first embodiment;

FIGS. 7A, 7B, and 7C are sectional views (No. 2) showing an example of a method of manufacturing the display apparatus (display panel) according to the first embodiment;

FIGS. 8A and 8B are sectional views (No. 3) showing an example of a method of manufacturing the display apparatus (display panel) according to the first embodiment;

FIG. 9 is a schematic view showing an interference calculation model for the device structure of an organic EL element as a comparison target in the first embodiment;

FIGS. 10A and 10B are respectively a schematic view showing the optical paths of applied light beams assumed in the interference calculation model according to the comparison target and a conceptual view showing the definitions of the positive directions of the amplitudes of incident light, reflected light, and transmitted light in the interference calculation model;

FIG. 11 is a table (No. 1) showing a refractive index with respect to each wavelength of a medium used for calculation in the interference calculation model according to the comparison target;

FIG. 12 is a table (No. 2) showing a refractive index with respect to each wavelength of a medium used for calculation in the interference calculation model according to the comparison target;

FIG. 13 is a graph showing an example of the calculation of a spectral intensity (interference effect) in the interference calculation model according to the comparison target;

FIG. 14 is a graph showing an example of the calculation of a radiance in the interference calculation model according to the comparison target;

FIG. 15 is a schematic view showing an interference calculation model for the device structure of an organic EL element according to the first embodiment;

FIG. 16 is a schematic view showing the optical paths of applied light beams assumed in the interference calculation model according to the first embodiment;

FIG. 17 is a graph showing an example of the calculation of a spectral intensity (interference effect) in the interference calculation model according to the first embodiment;

FIG. 18 is a graph showing an example of the calculation of a radiance in the interference calculation mode according to the first embodiment;

FIG. 19 is a graph showing an example of the peak shift of a radiance in the interference calculation model according to the first embodiment;

FIG. 20 is a graph showing a change in the spectrum of light from a light-emitting element experimentally manufactured on the basis of the interference calculation model according to the first embodiment;

FIGS. 21A, 21B, and 21C are graphs showing calculation results on the relationships between the thickness of a thick layer, chromaticity, and luminance in the interference calculation model (green (G)) according to the first embodiment;

FIGS. 22A, 22B, and 22C are graphs showing calculation results on the relationships between the thickness of a thick layer, chromaticity, and luminance in the interference calculation model (blue (B)) according to the first embodiment;

FIGS. 23A, 23B, and 23C are graphs showing calculation results on the relationships between the thickness of a thick layer, chromaticity, and luminance in the interference calculation model (red (R)) according to the first embodiment;

FIG. 24 is a schematic sectional view showing a panel structure in a display apparatus according to the second embodiment; and

FIGS. 25A, 25B, 25C, and 25D are sectional views showing an example of a method of manufacturing the display apparatus (display panel) according to the second embodiment.

### DETAILED DESCRIPTION OF THE INVENTION

A display apparatus and its manufacturing method according to the present invention will be described in detail with reference to embodiments. The following embodiments exemplify a case in which organic EL elements comprising organic EL layers formed by application of a polymer-based organic material by using the ink-let method, nozzle coating method, or the like that is excellent in process controllability and productivity are used as light-emitting elements constituting display pixels.

<Display Panel>

A display panel (organic EL panel) and display pixels that are used for the display apparatus according to the present invention will be described first.

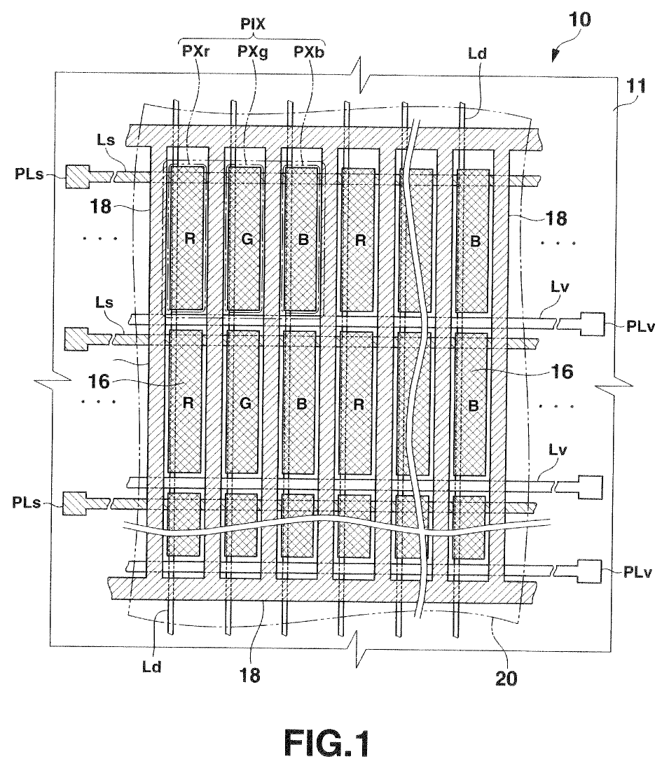

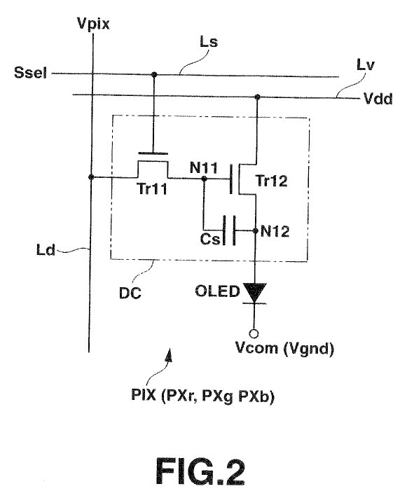

FIG. 1 is a schematic plan view showing an example of the pixel array state of the display panel used for the display apparatus according to the present invention. FIG. 2 is an equivalent circuit diagram showing an example of the circuit arrangement of each of display pixels (light-emitting elements and pixel driving circuits) two-dimensionally arrayed on the display panel of the display apparatus according to the present invention. For the sake of convenience, the plan view of FIG. 1 shows only the relationship between the arrangement of pixel electrodes provided for the respective display pixels (color pixels) and the structure of interconnection layers and the layout relationship between banks (partitions) that define the formation areas of the respective display pixels, when viewed from one surface side (organic EL element formation side) of the display panel (or an insulating substrate), while not illustrating transistors and the like in a pixel driving circuit shown in FIG. 2 that is provided for each display pixel to drive the organic EL element of each display pixel to emit light. Referring to FIG. 1, for the sake of convenience, pixel electrodes, interconnection layers, and banks are hatched to clearly indicate their arrangement.

As shown in FIG. 1, the display apparatus (display panel) according to the present invention has combinations of color pixels PXr, PXg, and PXb of three colors, i.e., red (R), green (G), and blue (B), formed on one surface side of an insulating substrate 11 such as a glass substrate. These combinations of color pixels (corresponding to a multiple of three), each comprising color pixels PXr, PXg, and PXb, are arrayed in the row direction (the horizontal direction on the drawing) repeatedly. Combinations of color pixels PXr, PXg, and PXb of the same colors are arrayed in the column direction (the vertical direction on the drawing). A combination of the adjacent color pixels PXr, PXg, and PXb of three colors R, G, and B constitute one display pixel PIX, and the apparatus is configured to perform color display by display driving operation to be described later.

As shown in FIG. 1, on a display panel 10, the image formation areas (the pixel areas of the respective colors) of the color pixels PXr, PXg, and PXb of the same colors arrayed in the column direction are defined by banks (partitions) 18 that protrude from one surface side of the insulating substrate 11 and are arranged in a planar palisade or lattice pattern. In addition, flat pixel electrodes (e.g., anode electrodes) 16 are formed in the pixel formation areas of the color pixels PXr, PXg, and PXb. In addition, data lines Ld are arranged in the column direction (the vertical direction on the drawing) to be parallel to the arrangement direction of the banks 18. Furthermore, selection lines Ls and power supply voltage lines (e.g., anode lines) Lv are arranged in the row direction (the horizontal direction on the drawing) perpendicular to the data lines Ld. A terminal pad PLs is provided at one end portion of each selection line Ls. A terminal pad PLv is provided at one end portion of each power supply voltage line Lv.

As shown in, for example, FIG. 2, each of the color pixels PXr, PXg, and PXb of the display pixel PIX has a circuit arrangement comprising a pixel driving circuit (corresponding to the above pixel circuit) DC including one or more transistors (e.g., amorphous silicon thin-film transistors) on the insulating substrate 11 and an organic EL element (light-emitting element) OLED that emits light when the emission driving current generated by the pixel driving circuit DC is supplied to the pixel electrode 16.

More specifically, as shown in, for example, FIG. 2, the pixel driving circuit DC comprises a transistor (selection transistor) Tr11 having a gate terminal, drain terminal, and source terminal respectively connected to the selection line Ls, the data line Ld provided in the column direction of the display panel 10, and a contact N11, a transistor (emission driving transistor) Tr12 having a gate terminal, drain terminal, and source terminal respectively connected to the contact N11, the power supply voltage line Lv, and a contact N12, and a capacitor Cs connected between the gate terminal and source terminal of the transistor Tr12.

Here, as the transistors Tr11 and Tr12, n-channel thin-film transistors (field effect transistors) are used. If the transistors Tr11 and Tr12 are of the p-channel type, the source and drain terminals are reversed. The capacitor Cs is the parasitic capacitance formed between the gate and source of the transistor Tr12, the auxiliary capacitance additionally provided between the gate and source, or a capacitance component comprising the parasitic capacitance and the auxiliary capacitance.

The organic EL element OLED has an anode terminal (the pixel electrode 16 serving as an anode electrode) connected to the contact N12 of the pixel driving circuit DC (the output terminal of the pixel driving circuit). The cathode terminal (cathode electrode) of the organic EL element OLED is integrally formed with an opposed electrode 20 and is directly or indirectly connected to a predetermined reference voltage Vcom (e.g., a ground potential Vgnd). The opposed electrode 20 is made of a single electrode layer (solid electrode) such that it commonly faces the pixel electrodes 16 of the display pixels PIX two-dimensionally arranged on the insulating substrate 11. With this structure, the reference voltage Vcom is commonly applied to the display pixels PIX.

In the display pixel PIX (the pixel driving circuit DC and the organic EL element OLED) shown in FIG. 2, the selection line Ls is connected to a selection driver (not shown), and a selection signal Ssel for setting the display pixels PIX (color pixels PXr, PXg, and PXb), arrayed in the row direction of the display panel 10, in a selected state is applied to the selection line Ls at a predetermined timing. The data line Ld is connected to a data driver (not shown), and a tone signal Vpix corresponding to display data is applied to the data line Ld at a timing synchronized with the selected state of the display pixel PIX.

In addition, the power supply voltage line Lv is directly or indirectly connected to, for example, a predetermined high-potential power supply. A predetermined high voltage (power supply voltage Vdd) higher in potential than the reference voltage Vcom applied to the opposed electrode 20 is applied to the power supply voltage line Lv to supply an emission driving current in accordance with display data to the pixel electrode 16 of the organic EL element OLED provided for each display pixel PIX (color pixels PXr, PXg, and PXb).

That is, in the pixel driving circuit DC shown in FIG. 2, the power supply voltage Vdd and the reference voltage Vcom are respectively applied to the two ends of a combination of the transistor Tr12 and the organic EL element OLED connected in series in each display pixel PIX (the drain terminal of the transistor Tr12 and the cathode terminal of the organic EL element OLED) to apply a forward bias to the organic EL element OLED, thereby making the organic EL element OLED ready for light emission. In addition, the current value of an emission driving current flowing in the organic EL element OLED is controlled in accordance with the tone signal Vpix.

In driving control operation of each display pixel PIX having such a circuit arrangement, first of all, the selection driver (not shown) applies the selection signal Ssel of a selection level (ON level, e.g., high level) to the selection line Ls in a predetermined selection period to turn on the transistor Tr11 and set it in the selected state. In synchronism with this timing, the data driver (not shown) is controlled to apply the tone signal Vpix having a voltage value corresponding to display data to the data line Ld. With this operation, a potential corresponding to the tone signal Vpix is applied to the contact N11 (i.e., the gate terminal of the transistor Tr12) via the transistor Tr11.

In the pixel driving circuit DC having the circuit arrangement shown in FIG. 2, the current value of the drain-source current (i.e., the emission driving current flowing in the organic EL element OLED) of the transistor Tr12 is determined by the drain-source potential difference and gate-source potential difference. In this case, the power supply voltage Vdd applied to the drain terminal (drain electrode) of the transistor Tr12 and the reference voltage Vcom applied to the cathode terminal (cathode electrode) of the organic EL element OLED are fixed values, the drain-source potential difference of the transistor Tr12 is fixed in advance by the power supply voltage Vdd and the reference voltage Vcom. Since the gate-source potential difference of the transistor Tr12 is uniquely determined by the potential of the tone signal Vpix, the current value of a current flowing between the drain and source of the transistor Tr12 can be controlled by the tone signal Vpix.

In this manner, when the transistor Tr12 is turned on in an ON state corresponding to the potential of the contact N11 of the transistor Tr12 (an ON state corresponding to the tone signal Vpix), an emission driving current having a current value corresponding to a luminance level flows from the power supply voltage Vdd on the high potential side to the reference voltage Vcom (ground potential Vgnd) on the low potential side via the transistor Tr12 and the organic EL element OLED. As a result, the organic EL element OILED emits light at the luminance level corresponding to the tone signal Vpix (i.e., display data). At this time, electric charge is accumulated (charged) in the capacitor Cs between the gate and source of the transistor Tr12 on the basis of the tone signal Vpix applied to the contact N11.

In a non-selection period after the above selection period, when the selection signal Ssel of a non-selection level (OFF level, e.g., low level) is applied to the selection line Ls, the transistor Tr11 of the display pixel PIX is turned off and set in the non-selection state. As a result, the data line Ld is electrically disconnected from the pixel driving circuit DC (more specifically, the contact N11). At this time, holding the electric charge accumulated in the capacitor Cs will hold a voltage corresponding to the tone signal Vpix (i.e., the gate-source potential difference) at the gate terminal of the transistor Tr12.

As in emission operation in the above selection state, an emission driving current flows from the power supply voltage Vdd to the organic EL element OLED via the transistor Tr12, thereby continuing the emission operation state. This emission operation state is controlled to, for example, continue for a one-frame period until the next tone signal Vpix is applied (written). Sequentially executing such driving control operation for all the display pixels PIX (the color pixels PXr, PXg, and PXb) two-dimensionally arrayed on the display panel 10 for, for example, each row can execute image display operation of displaying desired image information.

Referring to FIG. 2, the pixel driving circuit DC provided for the display pixel PIX has the circuit arrangement corresponding to a voltage designation type gray scale control scheme of controlling the current value of an emission driving current to be supplied to the organic EL element OLED by adjusting (designating) the voltage value of the tone signal Vpix to be written in each display pixel PIX (more specifically, the gate terminal of the transistor Tr12 of the pixel driving circuit DC; the contact N11) in accordance with display data, thereby causing the element to emit light at a desired luminance level. However, it suffices to use a pixel driving circuit having a circuit arrangement of a current designation type gray scale control scheme of controlling the current value of an emission driving current to be supplied to the organic EL element OLED by adjusting (designating) the current value of a current to be supplied (written) in each display pixel PIX in accordance with display data, thereby causing the element to emit light at a desired luminance level.

### FIRST EMBODIMENT

(Device Structure of Display Pixel)

The device structure (plan layout and sectional structure) of a display pixel (a pixel driving circuit and an organic EL element) having the above circuit arrangement will be described in detail next.

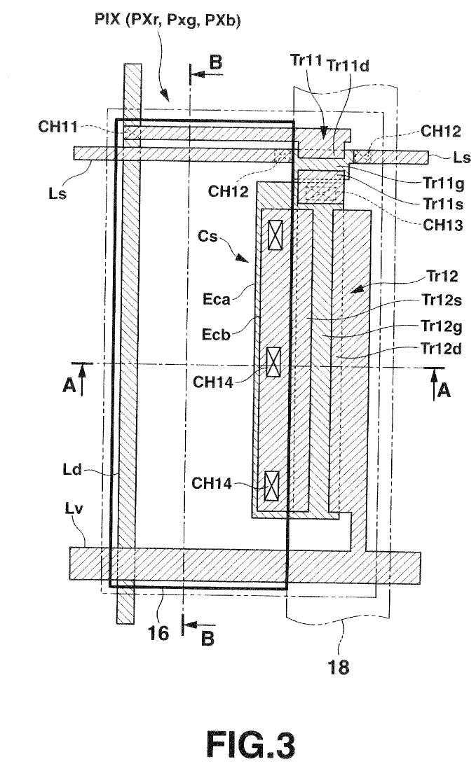

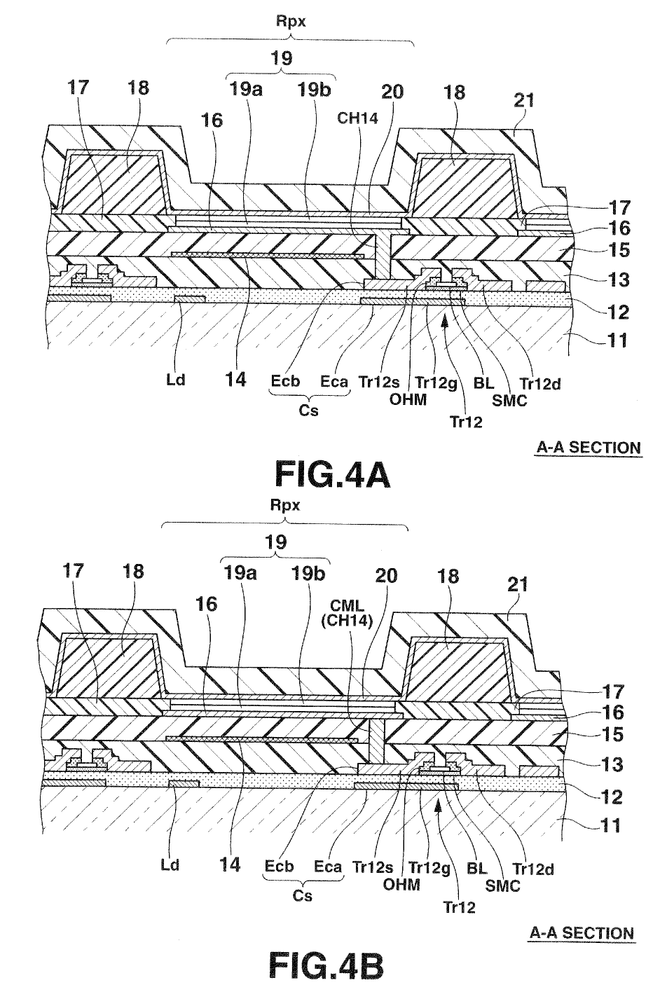

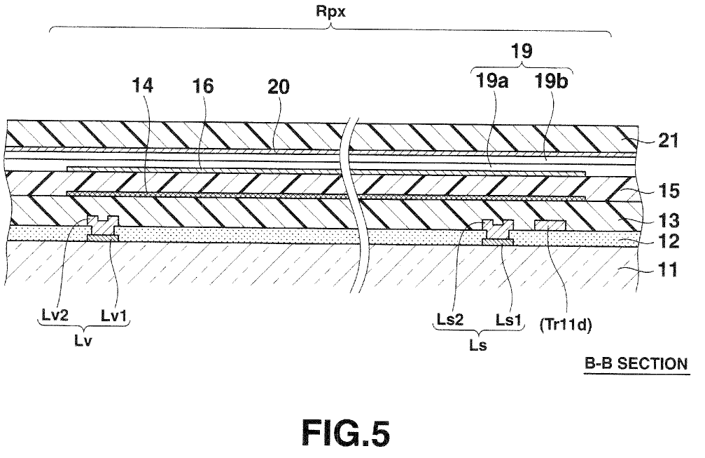

FIG. 3 is a plan layout showing an example of a display pixel that can be applied to a display apparatus (display panel) according to the first embodiment. FIG. 3 shows a plan layout of a specific one of color pixels PXr, PXg, and PXb of red (R), green (G), and blue (B) of a display pixel PIX shown in FIG. 1. Note that FIG. 3 mainly shows a layer on which the transistors, interconnection layers, and the like of a pixel driving circuit DC are formed. For the sake of convenience, the respective interconnection layers and the respective electrodes are hatched to clearly indicate their arrangement. FIGS. 4A, 4B, and 5 are schematic sectional views showing the A-A section and B-B section of the display pixel PIX having the plan layout shown in FIG. 3. FIG. 4A shows the first example of the A-A section of the display pixel PIX. FIG. 4B shows the second example of the A-A section of the display pixel PIX.

More specifically, the display pixel PIX (color pixels PXr, PXg, and PXb) shown in FIG. 2 is designed such that a selection line Ls and a power supply voltage line Lv are provided in a pixel formation area (the organic EL element formation area of each of the color pixels PXr, PXg, and PXb) set on one surface side of an insulating substrate 11. The selection line Ls and the power supply voltage line Lv extend in the row direction (the horizontal direction on the drawing) in the upper and lower margin areas of the plan layout, respectively, shown in FIG. 3. In addition, a data line Ld extends in the column direction (the vertical direction on the drawing) in the left margin area of the above plan layout so as to intersect the lines Ls and Lv at right angles. A bank (to be described in detail later) 18 is provided in the right margin region of the above plan layout so as to extend across adjacent color pixels on the right side in the column direction.

As shown in, for example, FIGS. 3 to 5, the data line Ld is provided on a lower layer side (insulating substrate 11 side) than the selection line Ls and the power supply voltage line Lv. The data line Ld is formed in the same step as gate electrodes Tr11g and Tr12g by patterning a gate metal layer for the formation of the gate electrodes Tr11g and Tr12g of transistors Tr11 and Tr11g. The data line Ld is connected to a drain electrode Tr11d of the transistor Tr11 via a contact hole CH11 provided in a gate insulating film 12 covering the data line Ld.

The selection line Ls and the power supply voltage line Lv are provided on an upper layer side than the data line Ld and the gate electrodes Tr11g and Tr12g.

The selection line Ls and the power supply voltage line Lv are formed in the same step as source electrodes Tr11s and Tr12s and drain electrodes Tr11d and Tr12d by patterning source and drain metal layers for the formation of the source electrodes Tr11s and Tr12s and drain electrodes Tr11d and Tr12d of the transistors Tr11 and Tr12.

The selection line Ls is connected to the gate electrode Tr11g via contact holes CH12 formed in the gate insulating films 12 located at the two ends of the gate electrode Tr11g of the transistor Tr11. The power supply voltage line Lv is integrally formed with the drain electrode Tr12d of the transistor Tr12.

As shown in, for example, FIG. 5, the selection line Ls and the power supply voltage line Lv can have an interconnection structure having lower interconnection layers Ls1 and Lv1 stacked on upper interconnection layers Ls2 and Lv2 to achieve a reduction in resistance. For example, the lower interconnection layers Ls1 and Lv1 are formed on the same layer as that of the gate electrodes Tr11g and Tr12g of the transistors Tr11 and Tr12. The lower interconnection layers Ls1 and Lv1 are formed in the same step as the gate electrodes Tr11g and Tr12g by patterning a gate metal layer for the formation of the gate electrodes Tr11g and Tr12g. As described above, the upper interconnection layers Ls2 and Lv2 are formed on the same layer as that of the source electrodes Tr11s and Tr12s and drain electrodes Tr11d and Tr12d of the transistors Tr11 and Tr12. The upper interconnection layers Ls2 and Lv2 are formed in the same step as the source electrodes Tr11s and Tr12s and the drain electrodes Tr11d and Tr12d by patterning a source/drain metal layer for the formation of the source electrodes Tr11s and Tr12s and the drain electrodes Tr11d and Tr12d.

Note that the lower interconnection layers Ls1 and Lv1 each can be formed from a single metal layer or alloy layer made of a low-resistance metal or metals for a reduction in interconnection resistance, e.g., aluminum (Al), an aluminum alloy such as aluminum-titanium (AlTi) or aluminum-neodymium-titanium (AlNdTi), or copper (Cu), or can have a multilayer structure in which a transition-metal layer for a reduction in migration that is made of chromium (Cr), titanium (Ti), or the like is provided under the above low-resistance metal layer. Alternatively, the upper interconnection layers Ls2 and Lv2 each can have a multilayer structure comprising a transition metal layer for a reduction in migration that is made of chromium (Cr), titanium (Ti), or the like, and a low-resistance metal layer for a reduction in interconnection resistance that is made of aluminum, an aluminum alloy, or the like and is formed under the transition metal layer.

More specifically, as shown in, for example, FIG. 3, in the pixel driving circuit DC, the transistor Tr11 shown in FIG. 2 extends in the row direction, and the transistor Tr12 extends along the column direction. In this case, the transistors Tr11 and Tr12 have known field-effect type thin-film transistor structures, which respectively include the gate electrodes Tr11g and Tr12g, semiconductor layers SMC formed in areas corresponding to the gate electrodes Tr11g and Tr12g through the gate insulating film 12, and the source electrodes Tr11s and Tr12s and the drain electrodes Tr11d and Tr12d extending on the two end portions of the semiconductor layers SMC.

Note that channel protective layers BL made of silicon oxide, silicon nitride, or the like for the prevention of etching damage to the semiconductor layers SMC are formed on the semiconductor layers SMC on which the source electrodes Tr11s and Tr12s and drain electrodes Tr11d and Tr12d of the transistors Tr11 and Tr12 face each other. In addition, impurity layers OHM are formed between the source and drain electrodes and the semiconductor layers SMC to provide ohmic connection between the semiconductor layers SMC and the source electrodes Tr11s and Tr12s and the drain electrodes Tr11d and Tr12d.

As shown in FIG. 3, in correspondence with the circuit arrangement of the pixel driving circuit DC shown in FIG. 2, the gate electrode Tr11g of The transistor Tr11 is connected to the selection line Ls via the contact hole CH12 formed in the gate insulating film 12, and the drain electrode Tr11d of the transistor Tr11 is connected to the data line Ld via the contact hole CH11 formed in the gate insulating film 12.

As shown in FIGS. 3, 4A, and 4B, the gate electrode Tr12g of the transistor Tr12 is connected to the source electrode Tr11s of the transistor Tr11 via a contact hole CH13 formed in the gate insulating film 12, and the drain electrode Tr12d of the transistor Tr12 is integrally formed with the power supply voltage line Lv. The source electrode Tr12s (the output terminal of the pixel driving circuit) of the transistor Tr12 is connected to a pixel electrode 16 of an organic EL element OLED via a contact holes CH14 formed in a protective insulating film 13 and a light irradiation control insulating film 15 which is flat.

As shown in FIGS. 3, 4A, and 4B, a capacitor Cs comprises electrodes Eca and Ecb. The electrode Eca is integrally formed with the gate electrode Tr12g of the transistor Tr12 on the insulating substrate 11. The electrode Ecb is integrally formed with the source electrode Tr12s of the transistor Tr12 on the gate insulating film 12. The electrodes Eca and Ecb face each other through the gate insulating film 12. The protective insulating film 13 and the light irradiation control insulating film 15 on the electrode Ecb are provided with the contact holes CH14, and are connected to the pixel electrode 16 of the organic EL element OLED via the contact holes (opening portions: the first and second opening holes) CH14.

As shown in FIGS. 3 to 5, a flat reflecting layer 14 having a light reflection characteristic is formed on the protective insulating film (planarization film) 13 covering the transistors Tr11 and Tr12. The light irradiation control insulating film 15 is formed to cover the flat reflecting layer 14. The organic EL element OLED is connected to the source electrode Tr12s (the output terminal of the pixel driving circuit) of the transistor Tr12 via the contact holes CH14 extending through the protective insulating film 13 and the light irradiation control insulating film 15.

The organic EL element OLED includes an organic EL layer (light-emitting function layer) 19 having a hole transport layer 19a and an electron transport luminescent layer 19b, the pixel electrode (the first electrode, e.g., an anode electrode) 16 having a transmission characteristic with respect to at least light having a wavelength that is in part of a wavelength range of the light emitted from the organic EL layer 19, and an opposed electrode (the second electrode, e.g., a cathode electrode) 20 that is provided to face the pixel electrode 16 through the organic EL layer 19 and has a transmission characteristic with respect to at least the light having the wavelength that is in part of the wavelength range of the light emitted from the organic EL layer 19. The flat reflecting layer 14 is provided for each of the color pixels PXr, PXg, and PXb. The light irradiation control insulating film 15 is interposed between the flat reflecting layer 14 and the flat pixel electrode 16.

In the pixel formation area Rpx, the thickness of the light irradiation control insulating film 15 is even. Hence the shortest length between a bottom surface of the flat pixel electrode 16 and a top surface of the flat reflecting layer 14 is equal in the entire pixel formation area Rpx.

An underlying insulating film 17 is formed as an underlying film on the light irradiation control insulating film 15, and the bank 18 is provided on the underlying insulating film 17 so as to protrude. The pixel electrode 16 is an electrode to which an emission driving current is supplied from the transistor Tr12. A peripheral portion of the pixel electrode 16 overlaps the underlying insulating film 17. With this structure, an opening portion is formed in the underlying insulating film 17 and the bank 18 in each pixel formation area Rpx so as to expose the pixel electrode 16.

The organic EL layer 19 is formed in the pixel formation area Rpx surrounded by the bank 18. An opposed electrode 20 is a single electrode layer having a light transmission characteristic that is provided to face the pixel electrodes 16 two-dimensionally arrayed on the insulating substrate 11 through the organic EL layer 19 in each pixel formation area Rpx. The opposed electrode 20 extends on not only the pixel formation area Rpx but also the bank 18 that defines the pixel formation area Rpx.

In the panel structure shown in FIGS. 3 to 5, as described above, the selection line Ls and the power supply voltage line Lv are made to have the multilayer interconnection structures, and the upper interconnection layers Ls2 and Lv2 are formed by patterning the source/drain metal layer for the formation of the source electrodes Tr11s and Tr12s and drain electrodes Tr11d and Tr12d of the transistors Tr11 and Tr12. In addition, the selection line Ls is connected to the gate electrode Tr11g of the transistor Tr11 via the contact hole CH12, and the power supply voltage line Lv is integrally formed with the drain electrode Tr12d of the transistor Tr12. Furthermore, the data line Ld is formed by patterning the gate metal layer for the formation of the gate electrodes Tr11g and Tr12g of the transistors Tr11 and Tr12, and is connected to the drain electrode Tr11d of the transistor Tr11 via the contact hole CH11. However, the present invention is not limited to this. The selection line Ls and the power supply voltage line Lv may be formed under the gate insulating film 12 by patterning the above gate metal layer. The selection line Ls may be integrally formed with the gate electrode Tr11g, and the selection line Ls may be integrally formed with the drain electrode Tr11d by forming the data line Ld on the gate insulating film 12 by patterning the drain metal layer without providing the contact holes CH11 and CH12.

Note that the pixel electrode 16 can be electrically connected to the source electrode Tr12s of the transistor Tr12 of the pixel driving circuit DC (or the electrode Ecb on the other side of the capacitor Cs) by the following structure. As shown in FIG. 4A, the pixel electrode 16 can be directly connected to the source electrode Tr12s by filling the contact hole CH14 extending through the protective insulating film 13 and the light irradiation control insulating film 15 with an electrode material forming the pixel electrode 16.

Alternatively, as shown in FIG. 4B, the pixel electrode 16 can be connected to the source electrode Tr12s via a contact metal CML by filling the contact hole CH14 with the contact metal CML.

The banks 18 are the boundary areas between the display pixels PIX (the color pixels PXr, PXg, and PXb) two-dimensionally arrayed on a display panel 10 (the areas between the pixel electrodes 16), and are provided in the column direction of the display panel 10 (so as to have a planar palisade or lattice pattern on the entire display panel 10, as shown in FIG. 1). As shown in FIGS. 3, 4A, and 4B, in the above boundary areas, the transistors Tr12 extend in the column direction of the display panel 10 (the insulating substrate 11), and the banks 18 generally cover the transistors Tr12 and are formed on the underlying insulating film 17 formed between the pixel formation areas Rpx and the pixel electrodes 16 so as to continuously protrude from the surface of the insulating substrate 11. The areas that are surrounded by the banks 18 and extend in the column direction (the pixel formation areas Rpx of the display pixels PIX arrayed in the column direction (the vertical direction of FIG. 1)) are defined as organic compound material coating areas when the organic EL layers 19 (the hole transport layers 19a and the electron transport luminescent layer 19b) are formed.

Each bank 18 is formed by using, for example, a photosensitive resin material such that at least its surfaces (side and upper surfaces) are subjected to surface treatment to have liquid repellency with respect to an organic compound containing liquid applied to the pixel formation area Rpx.

A sealing layer 21 having a function as a protective insulating film (passivation film) covers the entire area of one surface of the insulating substrate 11 on which the pixel driving circuits DC, organic EL elements OLED, and the banks 18 are formed, as shown in FIGS. 4A, 4B, and 5. Alternatively, a sealing substrate made of a glass substrate or the like may be joined to the insulating substrate 11 so as to face it.

In the display panel 10 (display pixels PIX) having the above arrangement, an emission driving current having a current value based on a tone signal Vpix corresponding to display data supplied via the data line Ld flows between the source and drain of the transistor Tr12 and is supplied to the pixel electrode 16 of the organic EL element OLED. With this operation, the organic EL element OLED of each display pixel PIX (the color pixels PXr, PXg, and PXb) emits light at a desired luminance level corresponding to the above display data.

In the display panel 10 according to this embodiment, the pixel electrodes 16 and the opposed electrode 20 have a light transmission characteristic (a high transmittance with respect to visible light), and the flat reflecting layers 14 provided under the pixel electrodes 16 through the light irradiation control insulating films 15 have a light reflection characteristic (a high reflectance with respect to visible light). Accordingly, the light emitted from the organic EL layer 19 of each display pixel PIX is directly applied to the visual field side (upward in FIGS. 4A and 4B) via the opposed electrode 20 having the light transmission characteristic, and is reflected by the flat reflecting layer 14 having the light reflection characteristic below the light irradiation control insulating film 15 via the pixel electrode 16 having the light transmission characteristic and the light irradiation control insulating film 15 to be applied to the visual field side via the light irradiation control insulating film 15, the pixel electrode 16, and the opposed electrode 20. That is, the display panel 10 according to this embodiment has the top emission structure, and the circuit elements and interconnection layers of the pixel driving circuits DC formed on the insulating substrate 11 two-dimensionally overlap the organic EL elements OLED formed on the protective insulating film 13.

(Method of Manufacturing Display Apparatus)

A method of manufacturing the above display apparatus (display panel) will be described next.

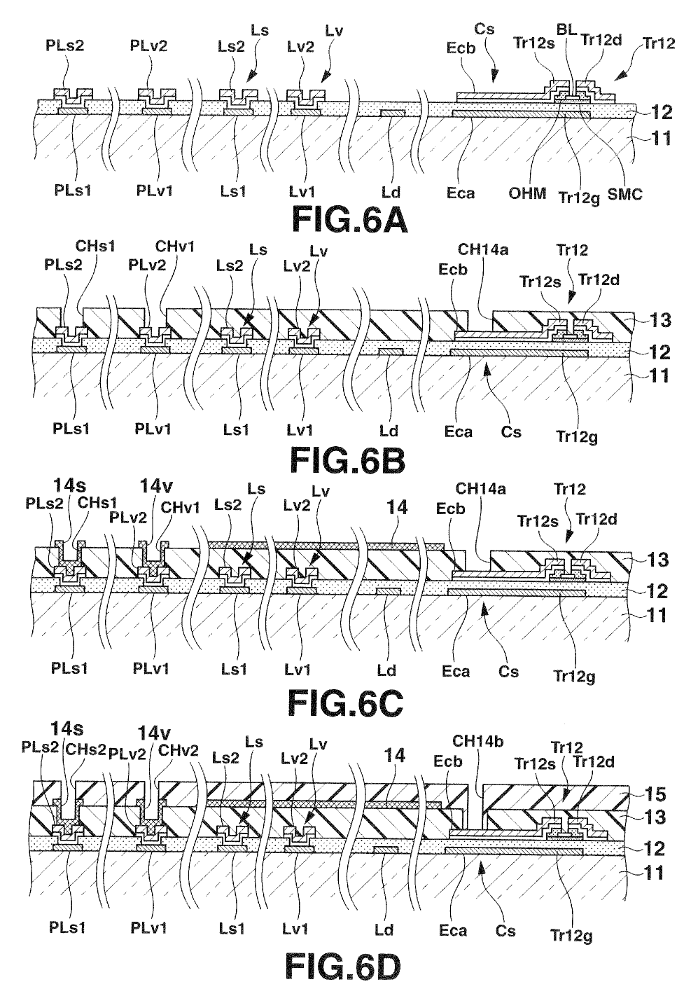

FIGS. 6A, 6B, 6C, 6D, 7A, 7B, 7C, 8A, and 8B are sectional views showing steps in the method of manufacturing the display apparatus (display panel) according to this embodiment. In order to clarify the characteristics of the method of manufacturing the display apparatus according to the present invention, a structure including parts (the transistor Tr12, capacitor Cs, data line Ld, selection line Ls, and power supply voltage line Lv) of the panel structure shown by the A-A section and B-B section in FIGS. 4 and 5, together with the terminal pad PLs provided at an end portion of the selection line Ls and the terminal pad PLv provided at an end portion of the power supply voltage line Lv shown in FIG. 1 will be extracted for convenience of explanation. In addition, the selection line Ls and the power supply voltage line Lv have multilayer interconnection structures for a reduction of resistance.

According to the method of manufacturing the above display apparatus (display panel), first of all, as shown in FIG. 6A, the transistors Tr11 and Tr12 and capacitor Cs of the pixel driving circuit DC and interconnection layers such as the data line Ld, selection line Ls, and power supply voltage line Lv (see FIGS. 4A, 4B, and 5) are formed in the pixel formation area Rpx of the display pixel PIX (the color pixels PXr, PXg, and PXb) set on one surface side (the upper surface side on the drawing) of the insulating substrate 11 such as a glass substrate.

More specifically, the following components are simultaneously formed on the insulating substrate 11 by patterning the same gate metal layer: the gate electrodes Tr11g and Tr12g, the electrode Eca on one side of the capacitor Cs that is integrally formed with the gate electrode Tr12g, the data line Ld, the lower interconnection layer Ls1 of the selection line Ls, a lower interconnection layer PLs1 of the terminal pad PLs connected to the selection line Ls, the lower interconnection layer Lv1 of the power supply voltage line Lv, and a lower interconnection layer PLv1 of the terminal pad PLv connected to the power supply voltage line Lv. Thereafter, the gate insulating film 12 is formed to cover the entire area of the insulating substrate 11. As shown in FIG. 3, in the area where the data line Ld, selection line Ls, and power supply voltage line Lv intersect each other, these lines are not electrically connected to each other (insulated) by, for example, not forming the lower interconnection layers Ls1 and Lv1 of the selection line Ls and power supply voltage line Lv.

Subsequently, for example, the semiconductor layers SMC made of amorphous silicon, polysilicon, or the like are formed in the areas corresponding to the gate electrodes Tr11g and Tr12g on the gate insulating film 12. The source electrodes Tr11s and Tr12s and the drain electrodes Tr11d and Tr12d are formed on the impurity layers OHM for ohmic contact on the two end portions of each of the semiconductor layers SMC.

At this time, the electrode Ecb on the other side of the capacitor Cs connected to the source electrode Tr12s is formed simultaneously with the upper interconnection layer Ls2 of the selection line Ls and an upper interconnection layer PLs2 of the terminal pad PLs, and the upper interconnection layer Lv2 of the power supply voltage line Lv and an upper interconnection layer PLv2 of the terminal pad PLv by patterning the same source/drain metal layer. This process forms the selection line Ls having the multilayer interconnection structure comprising the upper interconnection layer Ls2 and the lower interconnection layer Ls1 and the power supply voltage line Lv having the multilayer interconnection structure comprising the upper interconnection layer Lv2 and the lower interconnection layer Lv1.

The upper interconnection layers Ls2 and PLs2 of the selection line Ls and terminal pad PLs are formed to be electrically connected to the lower interconnection layers Ls1 and PLs1 of the selection line Ls and terminal pad PLs via the groove portions provided in the gate insulating film 12. In addition, the upper interconnection layers Lv2 and PLv2 of the power supply voltage line Lv and terminal pad PLv are formed to be electrically connected to the lower interconnection layers Lv1 and PLvl of the power supply voltage line Lv and terminal pad PLv via the groove portions provided in the gate insulating film 12.

Note that the source electrodes Tr11s and Tr12s and drain electrodes Tr11d and Tr12d of the transistors Tr11 and Tr12, the electrode Ecb on the other side of the capacitor Cs, the upper interconnection layer Ls2 (including the upper interconnection layer PLs2 of the terminal pad PLs) of the selection line Ls, and the upper interconnection layer Lv2 (including the upper interconnection layer PLv2 of the terminal pad PLv) of the selection line Ls each can have a multilayer interconnection structure comprising, for example, an aluminum alloy layer such as an aluminum-titanium (AlTi) or aluminum-neodymium-titanium (AlNdTi) layer and a transition-metal layer such as a chromium (Cr) layer in order to achieve reductions in interconnection resistance and migration.

As shown in FIG. 6B, the protective insulating film 13 having the function of a planarization film made of silicon nitride (SiN) or the like is formed to cover the entire area of one surface of the insulating substrate 11, including the transistors Tr11 and Tr12, the capacitor Cs, the upper interconnection layer Ls2 of the selection line is, and the upper interconnection layer Lv2 of the power supply voltage line Lv. The protective insulating film 13 is then etched (dry-etched) to form a contact hole (first opening portion) CH14a in which the upper surface of the source electrode Tr12s of the transistor Tr12 (or the electrode Ecb on the other side of the capacitor Cs) is exposed, and to simultaneously form opening portions CHs1 and CHv1 in which the upper surfaces of the upper interconnection layer PLs2 of the terminal pad PLs of the selection line Ls and the upper interconnection layer PLv2 of the terminal pad PLv of the power supply voltage line Lv are exposed.

As shown in FIG. 6C, a thin metal film having a light reflection characteristic (more specifically, a high reflectance with respect to the visible light region) and comprising a metal material such as silver (Ag) or aluminum (Al) or an alloy material such as aluminum-neodymium-titanium (AlNdTi) is formed on the protective insulating film 13, including the contact hole CH14a and the opening portions CHs1 and CHv1, by using the sputtering method or the like. The thin metal film is then patterned to form the flat reflecting layer (reflecting metal layer) 14 having a planar shape corresponding to each pixel formation area Rpx (each organic EL element OLED formation area), and to form reflecting metal layers 14s and 14v so as to connect them to the upper interconnection layers PLs2 and PLv2 of the terminal pads PLs and PLv that are exposed in the opening portions CHs1 and CHv1.

Subsequently, as shown in FIG. 6D, the light irradiation control insulating film 15 having, for example, a thickness of 2,000 nm or more, and the function of a planarization film is formed to cover the entire area of one surface of the insulating substrate 11, including the flat reflecting layer 14, the reflecting metal layers 14s and 14v, and the contact hole CH14a. The light irradiation control insulating film 15 is then etched to form a contact hole (second opening portion) CH14b, in the area where the contact hole CH14a has been formed, in which the upper surface of the source electrode Tr12s of the transistor Tr12 (or the electrode Ecb on the other side of the capacitor Cs) is exposed, and to simultaneously form opening portions CHs2 and CHv2 in which the upper surfaces of the reflecting metal layers 14s and 14v of the terminal pads PLs and PLv are exposed.

In this case, the thick film material that forms the light irradiation control insulating film 15 is a transparent insulating material having almost the same refractive index as that of the pixel electrode 16 formed on the light irradiation control insulating film 15 in the step to be described later. For example, silicon nitride (SiN) or the like can be used as this material. Alternatively, an organic material having a thermosetting property, in particular, (for example, acrylic-based resin, epoxy-based resin, or polyimide-based resin) can be used. In this case, the light irradiation control insulating film 15 having a relatively large thickness of 2,000 nm or more and the function of a planarization film that reduces the level differences of the surface of the insulating substrate 11 can be easily formed by applying a solution containing the above organic material on the insulating substrate 11.

In addition, if a photosensitive thick film material (organic material) is used as the light irradiation control insulating film 15, the contact hole CH14b and the opening portions CHs2 and CHv2 to be formed in the light irradiation control insulating film 15 can be formed by exposure/development processing after the application of the thick film material. Note that if a thick film material without photosensitivity is used as the light irradiation control insulating film 15, the contact hole CH14b and the opening portions CHs2 and CHv2 can be formed by forming a mask using a resist or thin metal film on the thick film material, dry-etching the light irradiation control insulating film 15, and removing the mask.

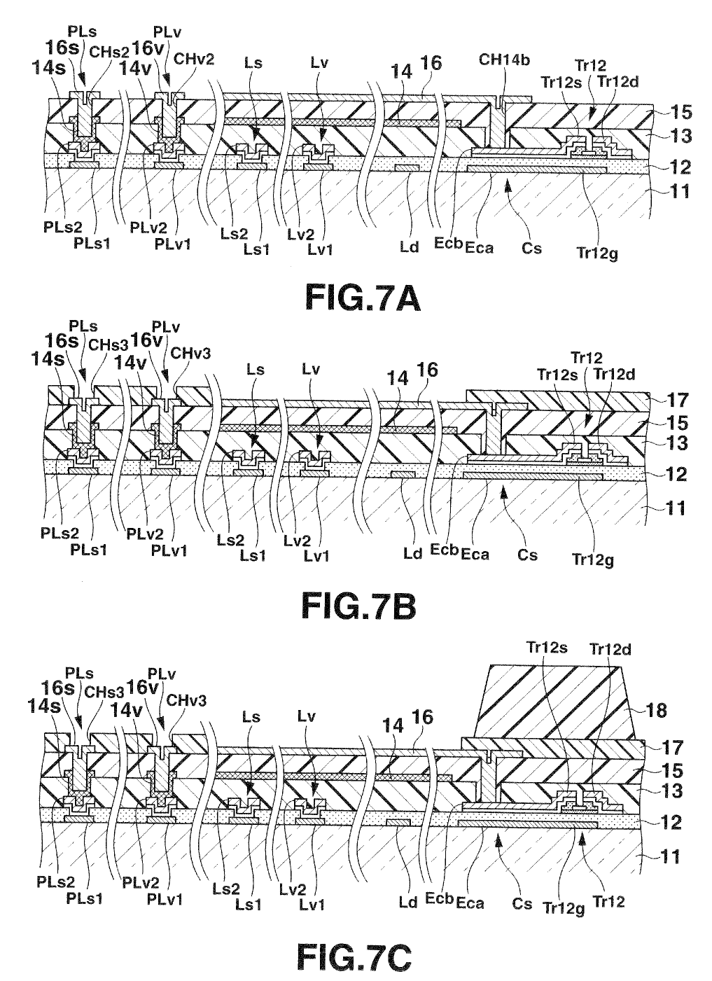

Subsequently, a conductive oxide metal layer made of a transparent electrode material (having a light transmission characteristic) such as indium tin oxide (ITO), indium zinc oxide (IZO), iridium tungsten oxide (IWO), or indium tungsten zinc oxide (IWZO) is formed thin on the entire area of one surface of the insulating substrate 11, including the contact hole CH14b and the opening portions CHs2 and CHv2, by using the sputtering method or the like. As shown in FIG. 7A, this conductive oxide metal layer is then patterned to form the pixel electrode (e.g., an anode electrode) 16 that is electrically connected to the source electrode Tr12s of the transistor Tr12 in the contact hole CH14b and extends on the light irradiation control insulating film 15 in the area corresponding to the pixel formation area Rpx (the area corresponding to the flat reflecting layer 14), and to form conductive oxide metal layers 16s and 16v so as to electrically connect them to the upper interconnection layers PLs2 and PLv2 of the terminal pads PLs and PLv via the reflecting metal layers 14s and 14v in the opening portions CHs2 and CHv2. This process forms the terminal pad PLs having the multilayer interconnection structure comprising the lower interconnection layer PLs1, upper interconnection layer PLs2, reflecting metal layer 14s, and conductive oxide metal layer 16s and the terminal pad PLv having the multiplayer interconnection structure comprising the lower interconnection layer PLv1, upper interconnection layer Lv2, reflecting metal layer 14v, and conductive oxide metal layer 16v.

In this step, the flat reflecting layer 14 is completely covered by the light irradiation control insulating film 15, and the reflecting metal layers 14s and 14v in the opening portions CHs2 and CHv2 are completely covered by the conductive oxide metal layer. Since the conductive oxide metal layer is patterned while the above layers are not exposed, cell reaction between the conductive oxide metal layer and the flat reflecting layer 14 and the reflecting metal layers 14s and 14v can be prevented. In addition, this prevents the flat reflecting layer 14 and the reflecting metal layers 14s and 14v from being over-etched or damaged by etching.

An insulating layer made of an inorganic insulating material such as silicon oxide film or silicon nitride film is formed to cover the entire area of one surface of the insulating substrate 11, including the pixel electrodes 16 and the conductive oxide metal layers 16s and 16v, by using the chemical vapor deposition method (CVD method) or the like. The insulating layer is then patterned to form the underlying insulating film 17 that covers the boundary areas between the adjacent display pixels PIX (the color pixels PXr, PXg, and PXb) (i.e., the areas between the adjacent pixel electrodes 16) and has, in each pixel formation area Rpx, an opening portion in which the upper surface of the pixel electrode 16 is exposed and opening portions CHs3 and CHv3 in which the conductive oxide metal layers 16s and 16v of the terminal pads PLs and PLv are exposed.

As shown in FIG. 7C, the banks 18 made of a photosensitive resin material such as a polyimide or acrylic material are formed on the underlying insulating film 17 formed in the boundary areas between the adjacent display pixels PIX. More specifically, the banks (partitions) 18 having a planar palisade or lattice pattern (see FIG. 1) including areas extending in the column direction of the display panel 10 are formed in the boundary areas between the display pixels PIX adjacent to each other in the row direction by patterning the photosensitive resin layer formed to cover the entire area of one surface of the insulating substrate 11 including the underlying insulating film 17.

With this process, the pixel formation areas Rpx of the display pixels PIX of the same color arrayed in the column direction of the display panel 10 (the formation areas of the organic EL layers 19 of the organic EL elements OLED) are defined by being surrounded by the banks 18, and the upper surfaces of the pixel electrodes 16 whose outer edges are defined by the opening portions formed in the underlying insulating film 17 are exposed.

After the insulating substrate 11 is cleaned by pure water, oxide plasma treatment, UV ozone treatment, or the like is performed for the surface of the pixel electrode 16 exposed in each pixel formation area Rpx to make it lyophilic with respect to an organic compound containing solution of a hole transport material and an electron transport luminescent material (to be described later). The insulating substrate 11 is then dipped in, for example, a fluorocarbon (fluorine compound) liquid-repellent solution and removed from it. Thereafter, the insulating substrate 11 is cleaned with pure water and dried to form a liquid-repellent thin film (coating) on the surface of each bank 18, thereby making the surface of each bank 18 repellent to an organic compound containing liquid.

With this process, on the same insulating substrate 11, only the surfaces of the banks 18 are subjected to liquid-repellent processing, and the surfaces of the pixel electrodes 16 exposed in the pixel formation areas Rpx defined by the banks 18 are held in a state in which they are not liquid-repellent (lyophilic). As described later, therefore, even if the organic EL layers 19 (electron transport luminescent layer 19b) are formed by applying the organic compound containing liquid, the leakage and overflow of the organic compound containing liquid to the adjacent pixel formation areas Rpx can be prevented. This can suppress color mixing between adjacent pixels and color the respective pixels in red, green, and blue.

Note that the term “liquid-repellency” used in this embodiment is defined as a state in which when an organic compound containing liquid containing a hole transport material that becomes the hole transport layer 19a, an organic compound containing liquid containing an electron transport luminescent material that becomes the electron transport luminescent layer 19b, or an organic solvent used for them is dropped onto the insulating substrate, the measured contact angle becomes 50° or more. The term “lyophilicity” antonymous to “liquid-repellency” is defined as a state in which the above contact angle is 40° or less, preferably 10° or less.

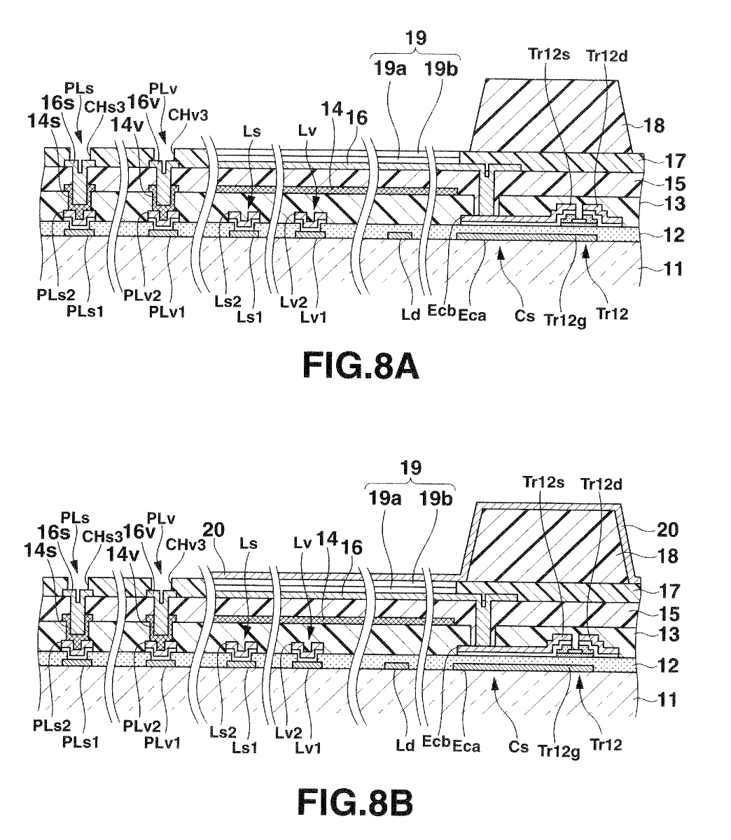

The hole transport layers 19a are formed by applying a hole transport material solution or dispersion to the pixel formation areas Rpx of the respective colors surrounded (defined) by the banks 18 by using the ink-jet method, the nozzle coating method, or the like, and heating/drying the solution or dispersion. Subsequently, the electron transport luminescent layers 19b are formed by applying an electron transport luminescent material solution or dispersion to the hole transport layers 19a and heating/drying the solution or dispersion. With this process, as shown in FIG. 8A, the organic EL layer 19 comprising the hole transport layer 19a and the electron transport luminescent layer 19b is stacked on the pixel electrode 16.

More specifically, as an organic compound containing liquid (compound containing liquid) containing an organic polymer-based hole transport material, for example, a polyethylenedioxythiophene/aqueous polystyrene sulfonate solution (PEDOT/PSS; a dispersion obtained by dispersing polyethylenedioxythiophene (PEDOT) as a conductive polymer and polystyrene sulfonate (PSS) in a water-based solvent) is applied to the pixel electrode 16. The applied solution is then heated and dried to remove the solvent and fix the organic polymer-based hole transport material on the pixel electrode 16, thereby forming the hole transport layer 19a as a carrier transport layer.

In addition, as an organic compound containing liquid (compound containing liquid) containing an organic polymer-based electron transport luminescent material, a solution obtained by solving a luminescent material containing a conjugate double bond polymer such as a polyparaphenylene-based material or polyfluorene-based material is applied onto the hole transport layer 19a. The solution is then heated and dried to remove the solvent and fix the organic polymer-based electron transport luminescent material on the hole transport layer 19a, thereby forming the electron transport luminescent layer 19b that is both a carrier transport layer and a luminescent layer.

Subsequently, as shown in FIG. 8B, a conductive layer (transparent electrode layer) having a light transmission characteristic is formed on the insulating substrate 11 including at least the pixel formation area Rpx of each display pixel PIX, and the common opposed electrode (e.g., a cathode electrode) 20 facing each pixel electrode 16 is formed on the organic EL layer 19 (the hole transport layer 19a and the electron transport luminescent layer 19b).

More specifically, as the opposed electrode 20, a film structure that is transparent in the thickness direction can be used, which is obtained by forming a thin film made of a metal material such as barium, magnesium, or lithium fluoride, which serves as an electron injection layer, by, for example, the vapor deposition method, and then stacking a transparent electrode layer made of ITO or the like on the thin film by the sputtering method or the like. In this case, the opposed electrode 20 is formed as a single conductive layer (solid electrode) that extends into the areas facing the pixel electrodes 16 and onto the banks 18 defining the pixel formation areas Rpx (the organic EL element OLED formation areas).

After the opposed electrode 20 is formed, the sealing layer 21 comprising a silicon oxide film, silicon nitride film, or the like is formed as a protective insulating film (passivation film) on the entire area of one surface of the insulating substrate 11 by the CVD method or the like, thereby completing the display panel 10 having a sectional structure like that shown in FIGS. 4A, 4B, and 5. Although not shown, a panel formed by joining a sealing cover or sealing substrate comprising a glass substrate or the like to the insulating substrate 11 so as to face it can be used instead of the panel structure shown in FIGS. 4A, 4B, and 5.

<Inspection of Functions and Effects>

The functions and effects of the display apparatus (display panel) having the above device structure will be inspected in detail next.

As described in “Background of the Invention”, as the light emission structures of organic EL elements, there are known a structure based on the bottom emission scheme of causing light from a luminescent layer to exit upon passing through a substrate on which the respective circuit elements of pixel driving circuits are formed, and a structure based on the top emission scheme of causing light to exit without passing through a substrate on which pixel driving circuits are formed. According to the latter scheme, since emitted light exits to the visual field side without passing through the pixel driving circuits (the substrate side), a large pixel aperture ratio can be set. This makes the latter scheme superior to the former scheme in terms of power consumption, panel lifetime, and the like.

The top emission scheme, however, has the following technical problems.

That is, the top emission scheme uses the panel structure in which the luminescent layer of each organic EL element is formed on the upper layer side of each pixel driving circuit comprising circuit elements such as thin-film transistors formed on a substrate, and hence it is necessary to form a planarization layer (protective insulating film) to reduce the level differences between circuit elements such as thin-film transistors. In addition, when a planarization layer is formed, it is necessary to form a contact hole to provide conduction between conductive layers formed on the upper and lower layer sides of the planarization layer, e.g., the source and drain electrodes of a thin-film transistor on the substrate and the pixel electrode of an organic EL element.

It is also necessary to provide each pixel formation area with a flat reflecting layer for reflecting light emitted from the luminescent layer of an organic EL element toward a pixel driving circuit (substrate). In this case, it is possible to use a device structure using a reflecting layer as an anode electrode (i.e., a pixel electrode). In general, however, a transparent conductive film (a conductive oxide metal layer made of a transparent electrode material) made of ITO or the like approximate in LUMO (the lowest unoccupied molecular orbital) to a hole injection layer is formed on a reflecting layer to cover it in order to improve the hole injection efficiency of an anode electrode, and the resultant electrode is used as an anode electrode (see Jpn. Pat. Appln. KOKAI Publication No. 8-330600). Note that in this specification, such a device structure will be referred to as a “comparison target” hereinafter.

When the present inventors have inspected a light emission structure based on such a top emission scheme by conducting various experiments, it has been found that an interference effect is produced between light from the luminescent layer that is directly applied to the visual field side and light reflected by the flat reflecting layer below the luminescent layer and applied to the visual field side. As will be described later, an interference effect varies in characteristic depending on the wavelength of light, and a characteristic curve representing the intensity of the interference effect has a peak. The peak position of the interference effect shifts depending on the emission position of the luminescent layer or the thickness of a pixel electrode comprising a transparent conductive film. This causes a change in emission intensity or chromaticity.

As in this embodiment, as a method of forming an organic EL layer (light-emitting function layer), in particular, a polymer coating method of forming a carrier transport layer by applying an organic polymer-based organic compound containing liquid, the thickness of a film formed on a pixel electrode in a pixel formation area is greatly influenced by the ambient temperature and humidity. That is, it is very difficult to control the film thickness to a predetermined value (uniform value). This causes noticeable variations in emission intensity and chromaticity between display panels and display pixels in the same display panel.

The above problems will be described in detail below by using an interference calculation model.

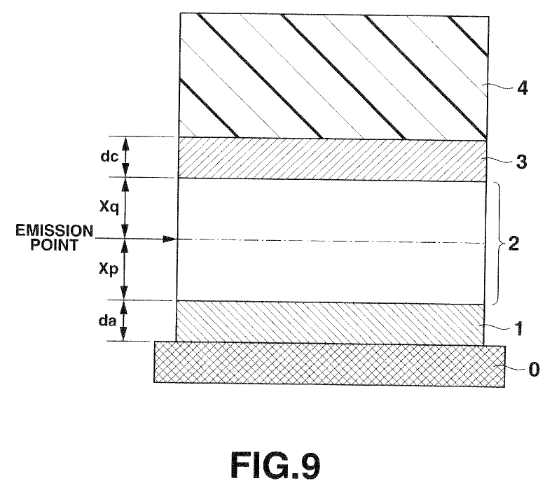

FIG. 9 is a schematic view showing an interference calculation model for the device structure of an organic EL element as a comparison target of this embodiment.

As shown in FIG. 9, assume that the interference calculation model according to the comparison target has a device structure in which a reflecting metal 0 is formed as the lowest layer that is made of a metal material (e.g., silver (Ag)) having a light reflection characteristic, and the following components are sequentially stacked on the reflecting metal 0: a transparent anode electrode 1 made of a transparent electrode material such as ITO, an electroluminescent layer 2 as a light-emitting function layer, a transparent cathode electrode 3 made of a transparent electrode material such as ITO, and a passivation film 4 made of silicon nitride (SiN).

In this case, the reflecting metal 0 corresponds to the flat reflecting layer 14 in the above embodiment, and the transparent anode electrode 1, electroluminescent layer 2, transparent cathode electrode 3, and passivation film 4 respectively correspond to the pixel electrode 16, organic EL layer 19, opposed electrode 20, and sealing layer 21.

Assume that the organic EL element emits light (applies light) at a given point in the electroluminescent layer 2 (corresponding to a position near the boundary between the hole transport layer 19a and the electron transport luminescent layer 19b in the above embodiment). Let Xp be the thickness of the electroluminescent layer 2 that corresponds to the distance from the emission point to the transparent anode electrode 1, and Xq be the thickness of the electroluminescent layer 2 that corresponds to the distance from the emission point to the transparent cathode electrode 3. In addition, let da and do be the thicknesses of the transparent anode electrode 1 and transparent cathode electrode 3. The thicknesses of the reflecting metal 0 and passivation film 4 are assumed to be infinite.

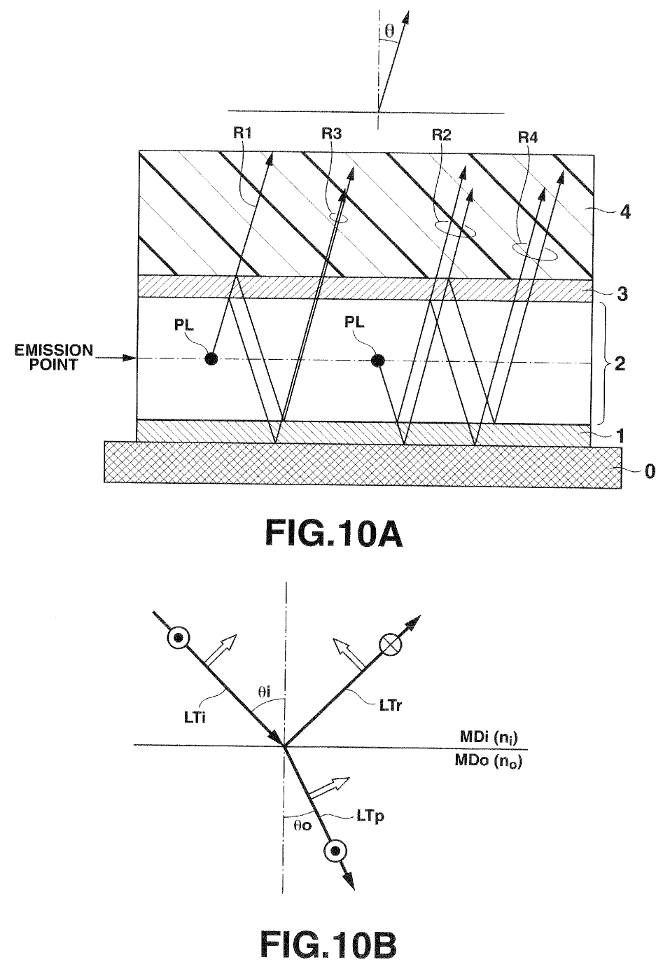

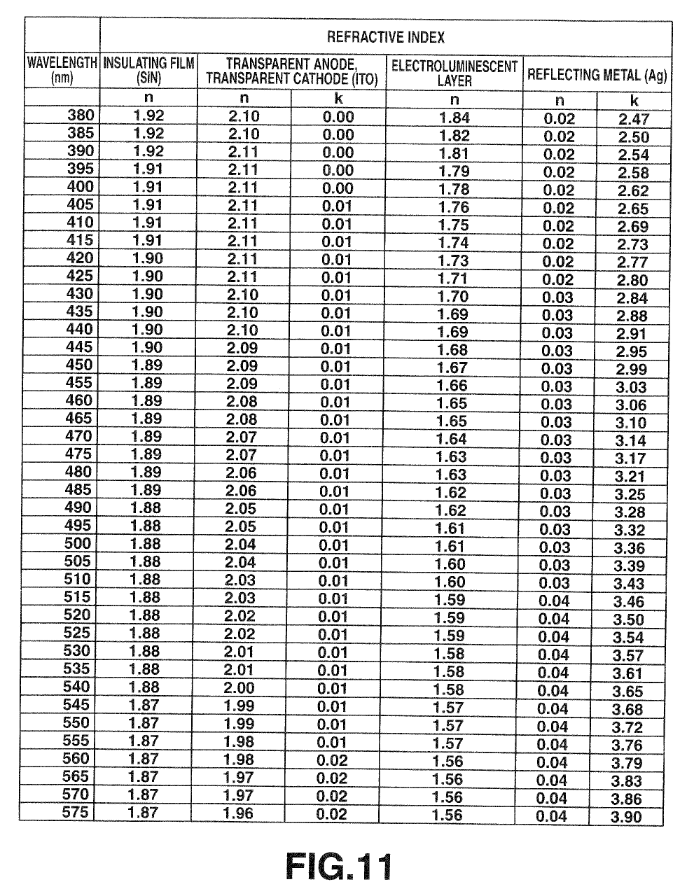

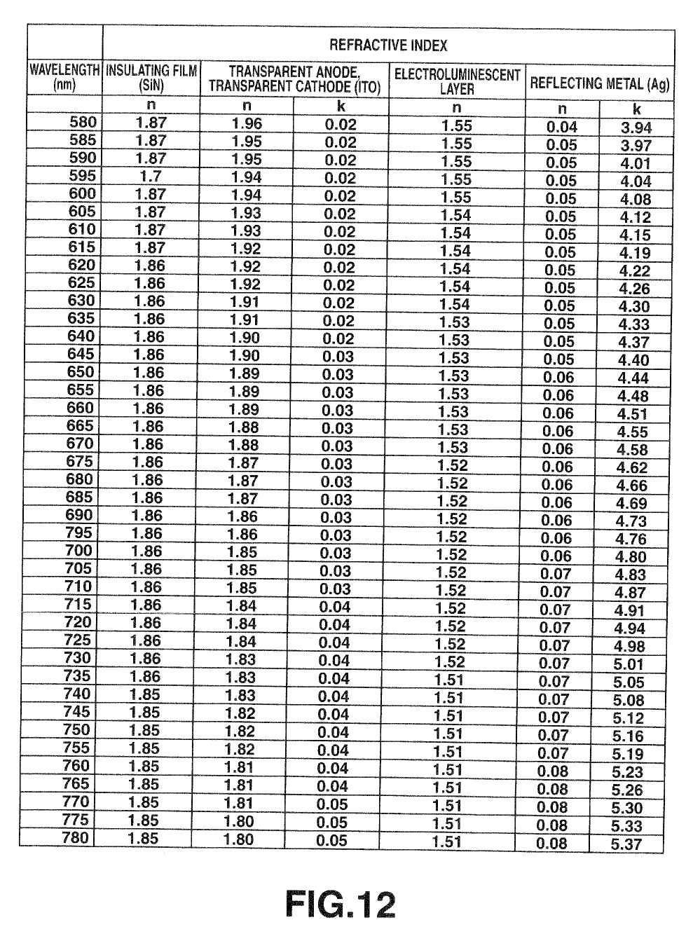

FIGS. 10A and 10B are a schematic view showing the optical paths of applied light beams assumed in the interference calculation model according to the comparison target and a conceptual view showing the definitions of the positive directions of the amplitudes of incident light, reflected light, and transmitted light in the interference calculation model. FIGS. 11 and 12 are tables each showing a refractive index with respect to each wavelength of a medium used for calculation in the interference calculation model according to the comparison target.

In a device structure like that shown in FIG. 9, as shown in FIG. 10A, it is expected that the overall interference effect is most greatly influenced by the interference effect between an optical path R1 of light propagating from an emission point PL in the electroluminescent layer 2 to an upper position on the drawing (extending through the transparent cathode electrode 3 and the passivation film 4 in the visual field direction) and an optical path R2 of light propagating from the emission point PL to a lower position on the drawing (to the reflecting metal 0 side), reflected by the surface of the transparent anode electrode 1 (the boundary surface between the electroluminescent layer 2 and the transparent anode electrode 1) or the surface of the reflecting metal 0 (the boundary surface between the transparent anode electrode 1 and the reflecting metal 0), and propagating to an upper position on the drawing. In this inspection process, interference calculation is performed including optical paths R3 and R4 in consideration of multiple reflection.

In this case, an example of optical paths of multiple reflection included in interference calculation is the optical path R3 of light that propagates from the emission point PL to an upper position on the drawing, is reflected by the surface of the transparent cathode electrode 3 (the boundary surface between the electroluminescent layer 2 and the transparent cathode electrode 3) or the surface of the passivation film 4 (the boundary surface between the transparent cathode electrode 3 and the passivation film 4), and propagates to a lower position on the drawing (the reflecting metal 0 side). Like the optical path R2, this light is then reflected by the surface of the surface of the transparent anode electrode 1 or the surface of the reflecting metal 0 again, and propagates to an upper position on the drawing. Another example is the optical path R4 of light that propagates from the emission point PL to a lower position on the drawing, is reflected by the surface of the transparent anode electrode 1 or the surface of the reflecting metal 0, and propagates to an upper position on the drawing, like the optical path R2. Like the optical path P3, this light is then reflected by the surface of the transparent cathode electrode 3 or the surface of the passivation film 4 again, propagates to a lower position on the drawing, is reflected by the surface of the transparent anode electrode 1 or the surface of the reflecting metal 0 again, and propagates to an upper position on the drawing.

In association with the optical paths R1 to R4 shown in FIG. 10A, the positive directions of the amplitudes of incident light, reflected light, and transmitted light are defined as shown in FIG. 10B. That is, assuming that light from a medium MDi (refractive index nᵢ) enters a medium MDo (refractive index nₒ), the positive direction of polarized light (s-polarized light) whose electric field vibrates vertically to the incident surface is vertical to the optical path when viewed from incident light LTi and transmitted light LTp, and coincides with an axial direction vertical to the incident surface. In addition, this direction is vertical to the optical path when viewed from reflected light LTr, and coincides with the incident surface direction (the boundary surface between the medium MDi and the medium MDo). On the other hand, the positive direction of polarized light (p-polarized light) whose electric field vibrates within the incident surface is vertical to the optical path when viewed from the incident light LTi and the transmitted light LTp, and is expressed as the front direction on the drawing (drawing surface). This direction is vertical to the optical path when viewed from the reflected light LTr, and is expressed as the rear direction on the drawing (drawing surface).

Referring to FIG. 10B, an amplitude reflectance r_{i,o} and an amplitude transmittance t_{i,o} at each boundary surface (interface) can be represented by

$$\begin{matrix}{r}_{i , o} = \frac{{Y}_{o} - {Y}_{i}}{{Y}_{o} + {Y}_{i}} , & ( 11 ) \\ {t}_{i , o} = \frac{2 {( {Y}_{o} {Y}_{i} )}^{1 / 2}}{{Y}_{o} + {Y}_{i}} {( \frac{cos {θ}_{i}}{cos {θ}_{o}} )}^{1 / 2} . & ( 12 )\end{matrix}$$

Here, θᵢ is the incident angle and reflection angle, and θₒ is the refraction angle. In addition, Yᵢ and Yₒ can be expressed as

Yᵢ=nᵢ·cos θᵢ, Yₒ=nₒ/cos θₒ, (for s-polarized light), (13)

Yᵢ=nᵢ/cos θᵢ, Yₒ=nₒ·cos θₒ, (for p-polarized light), (14)

Note that the refractive indexes corresponding to the wavelengths of media used for calculation in the interference calculation model according to the above comparison target are those written in FIGS. 11 and 12.

A spectral intensity I(λ) (corresponding to an interference effect) of light applied from an organic EL layer to the visual field side (the passivation film 4 side) through the optical paths R1 to R4 shown in FIG. 10A can be represented by equation (15) given below on the basis of equations (11) to (14). The spectral intensity I(λ) calculated by equation (15) corresponds to a multiple reflection model, and indicates the ratio of the intensity of light irradiated outside to the intensity (amplitude) of light isotropically applied from a luminescent layer for each wavelength λ. That is, the value obtained by this equation is a relative value with reference to the intensity (amplitude) of light at each wavelength of applied light, which is normalized to “1” when the value is equal to the intensity of light at each wavelength of applied light, to “2” when the intensity is double, and to “0” when the intensity becomes 0 upon cancellation by interference. The spectral intensity I(λ) is the value obtained without any consideration on the wavelength distribution (radiances) of applied light. As described above, obtaining the spectral intensities of s-polarized light and p-polarized light and averaging them can obtain a spectral intensity at each wavelength.

$$I ( λ ) = Abs [ {t}_{2 , 4} \{ 1 - {r}_{2 , 4} exp ( i γ p ) \} + {{r}_{2 , 4} {r}_{2 , 0} {t}_{2 , 4} exp ( i γ P + q ) \{ 1 - {r}_{2 , 0} exp ( i γ p ) \} / \sqrt{2} ]}^{2} \qquad ( 15 )$$

Letting r_{2,3} be the amplitude reflectance at the boundary surface between the electroluminescent layer 2 (incident side) and the transparent cathode electrode 3, r_{3,4} be the amplitude reflectance at the boundary surface between the transparent cathode electrode 3 (incident side) and the passivation film 4, r_{2,1} be the amplitude reflectance at the boundary surface between the electroluminescent layer 2 (incident side) and the transparent anode electrode 1, r_{1,0} be the amplitude reflectance at the boundary surface between the transparent anode electrode 1 (incident surface) and the reflecting metal 0, t_{2,3} be the amplitude transmittance between the electroluminescent layer 2 (incident side) and the transparent cathode electrode 3, t_{3,2} be the amplitude transmittance between the transparent cathode electrode 3 (incident side) and the electroluminescent layer 2, t_{3,4} be the amplitude transmittance between the transparent cathode electrode 3 (incident side) and the passivation film 4, t_{2,1} be the amplitude transmittance between the electroluminescent layer 2 (incident side) and the transparent anode electrode 1, and t_{1,2} be the amplitude transmittance between the transparent anode electrode 1 (incident side) and the electroluminescent layer 2, amplitude reflectances r_{2,4} and r_{2,0} and an amplitude transmittance t_{2,4} can be expressed by

r_{2,4}=r_{2,3}+t_{2,3}t_{3,2}r_{3,4}exp(iγc), (16)

t_{2,4}=t_{2,3}t_{3,4}exp(−iγc/2), (17)

r_{2,0}=r_{2,1}+t_{2,1}t_{1,2}r_{1,0}exp(iγa). (18)

In equations (15) to (18), a phase difference γa at the transparent anode electrode 1, a phase difference γc at the transparent cathode electrode 3, a phase difference γp at the electroluminescent layer 2 located on the transparent anode electrode 1 side with reference to the emission point PL, and a phase difference γp+q at the electroluminescent layer 2 can be expressed by

γa=4πn₁da·cos θ₁/λ, (19)

γc=4πn₃dc·cos θ₃/λ, (20)

γp=4πn₂Xp·cos θ₂/λ, (21)

γp+q=4πn₂(Xp+Xq)·cos θ₂/λ, (22)

In equations (19) to (22), θₘ (m is the sign of each layer in the interference calculation model shown in FIG. 10, and θ represents a viewing angle) can be obtained from Snell's law, i.e., nₘ·sin θₘ=sin θ. Since the refractive indexes of the electroluminescent layer 2, transparent anode electrode 1, and transparent cathode electrode 3 are approximate to each other, the influences of reflection are considered small, and hence the refractive indexes are calculated assuming that r_{2,3}=0 and r_{2,1}=0.

Light emitted from an organic EL layer is defined next. A radiance Le(λ) before interference is defined as

$$\begin{matrix}\begin{matrix}( λ p - λ \geq 0 ) \\ Le ( λ ) [ W / sr \times {m}^{2} ]\end{matrix} = {[ \begin{matrix}1 / exp ( \frac{1}{2} {( \frac{{λ}_{p} - λ}{σ} )}^{2} ) \cdot \\ \frac{{σ}^{2}}{( {( {λ}_{p} - λ )}^{2} + {σ}^{2} )}\end{matrix} ]}^{{λ}_{a}} , \\ \begin{matrix}( λ p - λ < 0 ) \\ Le ( λ ) [ W / sr \times {m}^{2} ]\end{matrix} = \begin{matrix}{[ 1 / exp ( \frac{1}{2} {( \frac{{λ}_{p} - λ}{σ} )}^{2} ) ]}^{2} \cdot \\ \frac{{σ}^{2}}{( {( {λ}_{p} - λ )}^{2} + {σ}^{2} )} .\end{matrix}\end{matrix} \} \qquad ( 23 )$$

Here, λp is the peak wavelength of the electroluminescent layer 2, σ is a line width, and γa is a short wavelength attenuation coefficient. Table 1 shows the parameters for the electroluminescent layers of red (R), blue (B), and green (G) used in this inspection process. Le′(λ)=I(λ)·Le(λ) obtained by multiplying Le at each wavelength by the spectral intensity I(λ) is the radiance to be finally observed at the viewing angle θ.

TABLE 1

| | Blue (B) | Green (G) | Red (R) |
|---|---|---|---|
| γa | 4 | 5 | 5 |
| λp | 462 | 534 | 643 |
| σ | 48.0 | 62.0 | 102.0 |

A chromaticity CIE(x, y) of each color is represented by x=X/(X+Y+Z) and y=Y/(X→Y+Z). Three stimulus values X, Y, and Z are calculated according to equations (24) to (26):

$$\begin{matrix}X = k {\int }_{380}^{780} {Le}^{′} ( λ ) x * ( λ ) d λ , & ( 24 ) \\ Y = k {\int }_{380}^{780} {Le}^{′} ( λ ) y * ( λ ) d λ , & ( 25 ) \\ Z = k {\int }_{380}^{780} {Le}^{′} ( λ ) z * ( λ ) d λ . & ( 26 )\end{matrix}$$

Here, x*(λ), y*(λ), and z*(λ) are three spectral stimulus values at the respective wavelengths. The above calculation is performed upon setting a coefficient k to five. In addition, luminance=Y×683/100.

The radiance Le′(λ), chromaticity CIE(x, y), and spectral intensity I(λ) finally derived from the respective parameters in the above manner were used for evaluation.

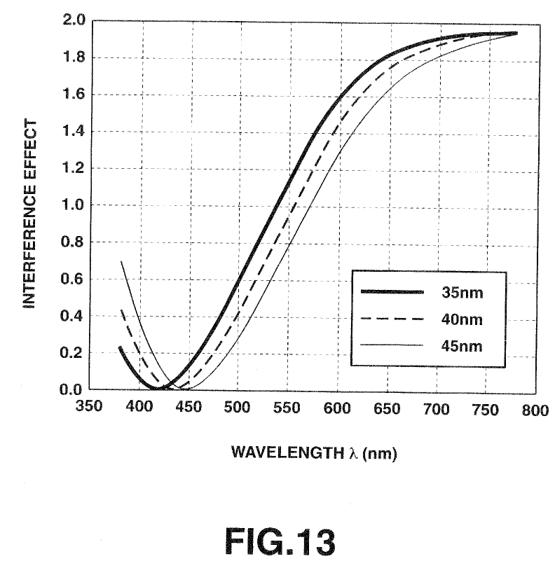

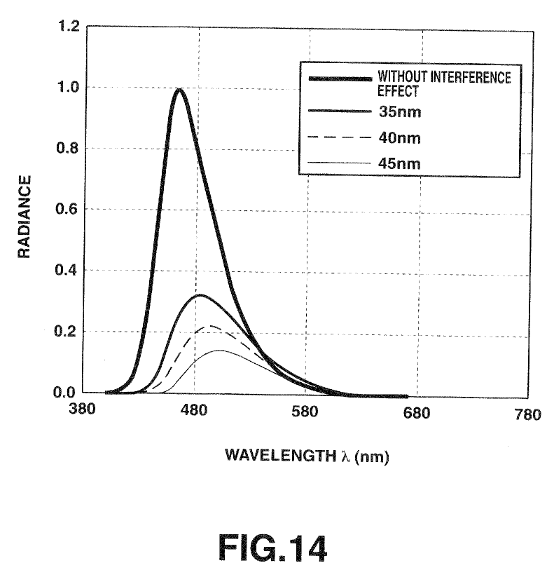

FIG. 13 is a graph showing an example of the calculation of spectral intensities (interference effects) in the interference calculation model according to the comparison target. FIG. 14 is a graph showing an example of the calculation of radiances in the interference calculation model according to the comparison target. In this case, FIG. 13 shows an example of the peak shift of the spectral intensity (interference effect) calculated by using the parameters shown in Table 2. FIG. 14 shows an example of the peak shift of the radiance influenced by the interference effect.

TABLE 2

| Color in Use | Blue (B) |
|---|---|
| θ [°] | 0 |
| dc [nm] | 100 |
| Xp [nm] | 35-45 |
| Xq [nm] | 70 |
| da [nm] | 50 |

As shown in FIG. 13, in a case in which only a thickness Xp of the electroluminescent layer 2 was changed, when the shift (fluctuation) of the peak of a spectral intensity was calculated with the thickness Xp being set to 35 nm, it was found that all the interference effects near wavelengths in the blue region (440 to 510 nm) were one or less, and hence the amplitudes acted in a direction to cancel out each other. In addition, there is a peak (minimum value) near a wavelength of 420 nm at which the amplitude reducing effect is maximized, and the peak tends to shift to the higher wavelength side as the thickness Xp increases to 40 nm and 45 nm. As shown in FIG. 14, the peak (maximum value) of the radiance influenced by the interference effect also tends to shift to the higher wavelength side as the thickness Xp of the electroluminescent layer 2 increases.

As described above, it was found that the peak position of an interference effect shifted depending on the emission position of the electroluminescent layer 2 or the thickness of the transparent anode electrode 1, and the emission intensity or chromaticity changed as a result. In this case, if the polymer coating method is selected as a film formation method for an organic EL element, the thickness of a film formed on a display pixel (pixel formation area) tends to noticeably depend on the ambient temperature and humidity. That is, it is very difficult to control the film thickness to a predetermined value. This causes variations in emission intensity and chromaticity between display panels and display pixels in the same display panel.

The above calculation examples are the results obtained when light is straightly emitted from the panel substrate (insulating substrate), i.e., viewing angle θ=0°. However, light obliquely exiting from the panel substrate, for example, at θ=30° or 60°, differs in interference route from light straightly exiting from the panel substrate, and hence is influenced by interference effects different from that described above. Table 3 shows the chromaticity and luminance of a green (G) organic EL element as the viewing angle θ changes. As the viewing angle θ increases from 0°, the chromaticity and luminance increase. When the viewing angle θ reaches 90°, the chromaticity increases to approximately 0.4, and the luminance becomes twice that when viewing angle θ=0°. These differences pose a problem as the viewing angle dependence of the display panel.

TABLE 3

| | Viewing angle θ[°] | | | | | | |
|---|---|---|---|---|---|---|---|
| | 0 | 15 | 30 | 45 | 60 | 75 | 90 |
| Chromaticity CIE_X | 0.538605 | 0.541221 | 0.54819 | 0.55754 | 0.566915 | 0.573782 | 0.576274 |
| Chromaticity CIE_Y | 0.451528 | 0.448517 | 0.440484 | 0.429674 | 0.418741 | 0.410614 | 0.407629 |
| Luminance | 290 | 305.5681 | 350.6611 | 416.0189 | 482.4947 | 528.1853 | 543.4382 |

The present invention, therefore, produces interference peaks in a wide range by providing the thick light irradiation control insulating film 15 having a light transmission characteristic between the transparent pixel electrode 16 serving as an anode electrode and the fiat reflecting layer 14 provided below the pixel electrode 16, as in the above embodiment (see FIGS. 4A, 4B, and 5). This allows suppressing variations in emission intensity and chromaticity due to the thickness of a luminescent layer (organic EL layer 19) and reducing the viewing angle dependence.

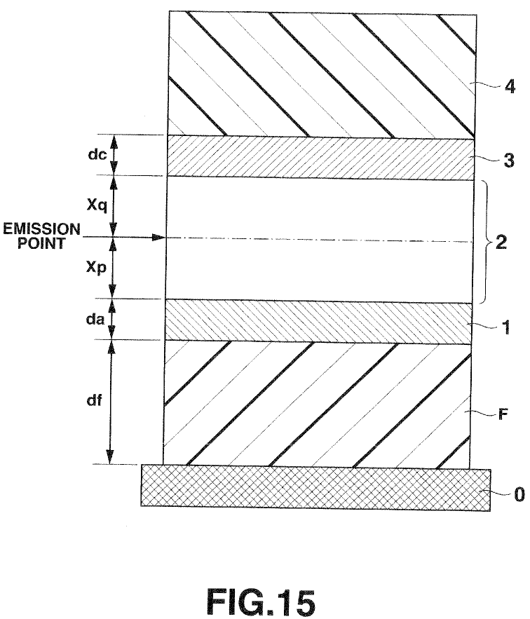

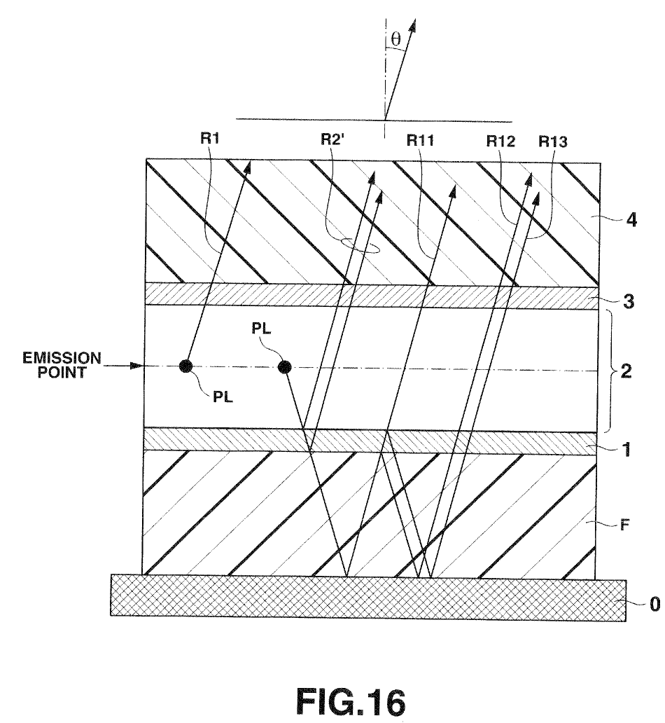

FIG. 15 is a schematic view showing an interference calculation model for the device structure of the organic EL element according to this embodiment. FIG. 16 is a schematic view showing the optical paths of applied light beams assumed in the interference calculation model according to this embodiment. The same reference numerals as in the above interference calculation model according to the comparison target denote the same components in this embodiment.

As shown in FIG. 15, the interference calculation model according to this embodiment has a device structure that is obtained by newly inserting (interposing) a thick layer F that has a thickness df and is made of a (transparent) insulating material having a light transmission characteristic between the reflecting metal 0 made of a metal material or the like that has a light reflection characteristic and the transparent anode electrode 1 made of a transparent electrode material such as ITO in the interference calculation model according to the comparison target (see FIG. 9). In this case, the thick layer F corresponds to the light irradiation control insulating film 15 in the above embodiment.

As shown in, for example, FIG. 16, as in the case of the above comparison target (see FIG. 1A), the optical paths of applied beam assumed in this device structure newly include optical paths R11 to R13 owing to the interposition of the thick layer F, in addition to an optical path R1 of light that propagates from an emission point PL in the electroluminescent layer 2 to an upper position on the drawing (propagates in the visual field direction through the transparent cathode electrode 3 and the passivation film 4) and an optical path R2′ of light that propagates from the emission point PL to a lower position on the drawing (the reflecting metal 0 side), is reflected by the surface of the transparent anode electrode 1 (the boundary surface between the electroluminescent layer 2 and the transparent anode electrode 1) or the surface of the thick layer F (the boundary surface between the transparent anode electrode 1 and the thick layer F), and propagates to an upper position on the drawing.

Examples of new optical paths included in interference calculation are the optical paths R11 to R13. The optical path R11 is the optical path of light that propagates from the emission point PL to a lower position on the drawing (the reflecting metal 0 side), is transmitted through the transparent anode electrode 1 and the thick layer F, is reflected by the surface of the reflecting metal 0 (the boundary surface between the thick layer F and the reflecting metal 0), and propagates to an upper position on the drawing (in the visual field direction through the transparent anode electrode 1, electroluminescent layer 2, transparent cathode electrode 3, and passivation film 4). The optical path R12 is the optical path of light that, like the optical path R11, propagates from the emission point PL to a lower position on the drawing, is reflected by the surface of the reflecting metal 0, propagates to an upper position on the drawing, is reflected again by the surface of the transparent anode electrode 1 (the boundary surface between the thick layer F and the transparent anode electrode 1), propagates to a lower position on the drawing, is further reflected by the surface of the reflecting metal 0, and propagates to an upper position on the drawing. The optical path R13 is the optical path of light that, like the optical path R11, propagates from the emission point PL to a lower position on the drawing, is reflected by the surface of the reflecting metal 0, propagates to an upper position on the drawing, is reflected again by the surface of the electroluminescent layer 2 (the boundary surface between the transparent anode electrode 1 and the electroluminescent layer 2), propagates to a lower position on the drawing, is further reflected by the surface of the reflecting metal 0, and propagates to an upper position on the drawing.

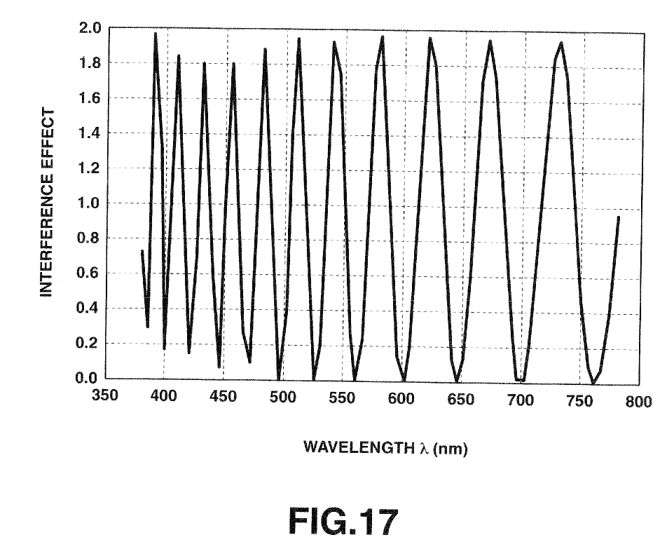

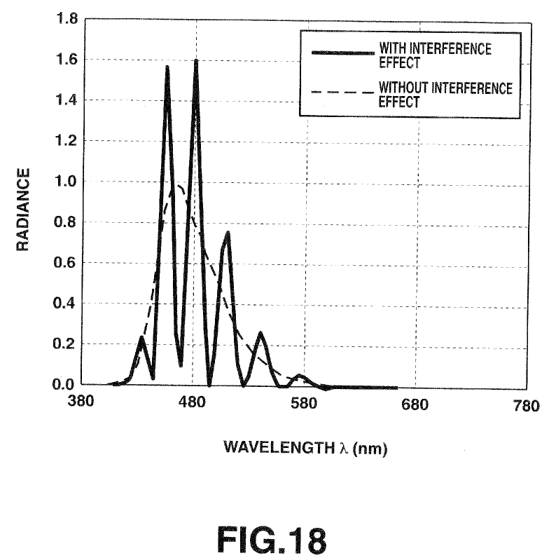

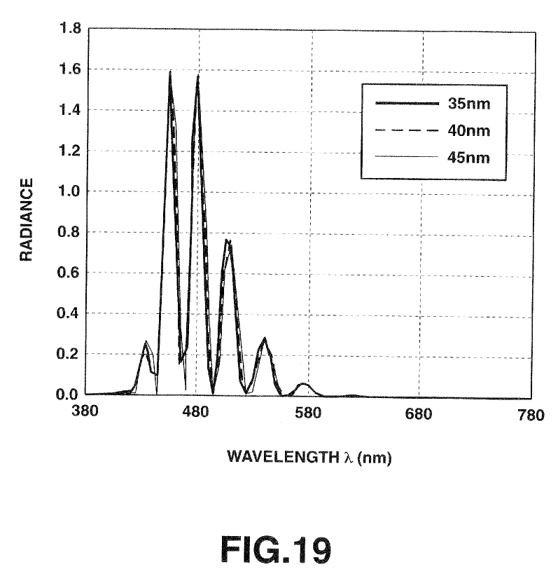

FIG. 17 is a graph showing an example of the calculation of a spectral intensity (interference effect) in the interference calculation model according to this embodiment. FIG. 18 is a graph showing an example of the calculation of a radiance in the interference calculation mode according to the embodiment. FIG. 17 shows an example of a spectral intensity (interference effect) calculated by using the parameters shown in Table 4 in the device structure that uses, as the thick layer F, an organic film having a thickness of 2.5 μm (2,500 nm) (refractive index n=1.6 is assumed for all the wavelengths). FIG. 18 shows an example of a radiance influenced by the interference effect. FIG. 19 is a graph showing an example of the peak shift of a radiance in the case of calculation using the parameters shown in Table 4.

TABLE 4

| Color in Use | Blue (B) |
|---|---|
| θ [°] | 0 |
| dc [nm] | 100 |
| Xp [nm] | 35-45 |
| Xq [nm] | 70 |
| df [nm] | 2500 |
| da [nm] | 50 |

As shown in FIG. 17, as compared with the comparison target described above (see FIG. 13), this spectral intensity has a periodic structure with many peaks (maximum and minimum values). In this application, an interference effect having this characteristic will be conveniently referred to as a “multiple peak effect”. When the influence of this multiple peak effect was inspected, it was found that a radiance spectrum influenced by the multiple peak effect had peaks as indicated by the thick solid line (thick line) in FIG. 18. Note that the characteristic curve indicated by the thin dotted line in FIG. 18 is a radiance spectrum free from the influence of the multiple peak effect, and is equivalent to the characteristic curve without interference effect shown in FIG. 14.

When the radiance spectrum calculated while the thickness Xp of the electroluminescent layer 2 that corresponds to the distance from the emission point PL to the transparent anode electrode 1 is changed is inspected, it is clear that the peak shift with respect to a change in the thickness Xp is reduced as compared with the comparison target described above (see FIG. 14). That is, it is found from the calculation that the multiple peak effect obtained by the insertion of the thick layer F is to suppress the peak shift of an interference effect due to a change in the thickness Xp of the electroluminescent layer 2 and the resultant peak shift of a radiance.

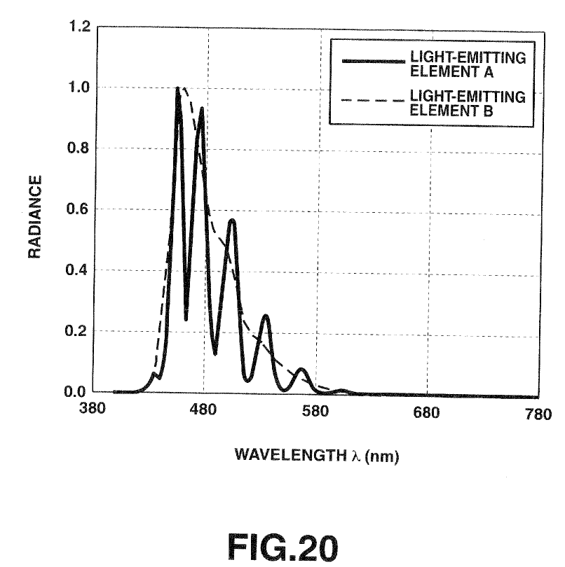

FIG. 20 is a graph showing a change in the spectrum of light from a light-emitting element experimentally manufactured on the basis of the interference calculation model according to this embodiment.

In order to inspect whether when the thick layer F was actually inserted on the basis of the above calculation result, a spectrum having many peaks could be observed, a light-emitting element (organic EL element) having different parameters was experimentally manufactured. A blue light-emitting element A having the same device structure as that of the interference calculation model shown in FIG. 15 was manufactured on a glass substrate. As the thick layer F, a transparent insulating thick film having refractive index n=1.6 and a thickness of 2.2 μm (2,200 nm) was used. As a reference element, a light-emitting element B having the same device structure as that of the light-emitting element A except for the reflecting metal 0 was manufactured. The emission spectra of these manufactured elements were compared with each other.

According to this comparison, it was clear that the spectrum of the light-emitting element having the multiple peak effect owing to the thick layer F had peaks, and hence it was confirmed that the above calculation model was correct. Note that the characteristic curve indicated by the thin dotted line in FIG. 20 is the spectrum of the light-emitting element B free from the influence of the multiple peak effect. It was confirmed that this spectrum had only one peak.

Based on this result, the refractive index and thickness of a thick layer that can minimize the spectrum shift are obtained. The following are evaluation criteria used in this case.

That is, deviations from the ideal values of the chromaticity and luminance are evaluated as the thickness of the electroluminescent layer 2 is changed.

The thickness Xp of the electroluminescent layer 2 that corresponds to the distance from the emission point PL to the transparent anode electrode 1 (i.e., the thickness of the hole transport layer (hole injection layer) 19a of the organic EL layer 19) is set to 35 to 45 nm, and the thickness Xq of the electroluminescent layer 2 that corresponds to the distance from the emission point PL to the transparent cathode electrode 3 (i.e., the thickness of the electron transport luminescent layer 19b of the organic EL layer 19) is set to 55 to 75 nm in the case of a green (G) light-emitting element (organic EL element), and to 60 to 80 nm in the case of a blue (B) or red (R) light-emitting element. While each thickness is changed in steps of 1 nm, the values of the chromaticity CIE(x, y) and luminance are obtained. As a result, 11×21=231 data are calculated. The average and error ((maximum value−minimum value)/average; in % notation) are obtained. It is then defined that as the average of the data is closer to the ideal value and the error is smaller, the thick layer is closer to the ideal layer that causes no change in color due to an interference effect and reduces a shift as the thickness changes.

First of all, averages and errors were calculated when the refractive index of the thick layer F was n=1.4 to 2.4, and thickness df=1000, 3000, and 5000 nm. Tables 6 to 8 show the calculation results obtained by using the parameters shown in Table 5.

TABLE 5

| | Blue (B) | Green (G) | Red (R) |
|---|---|---|---|
| Xqmin [nm] | 60 | 55 | 60 |
| Xqmax [nm] | 80 | 75 | 80 |

| | |
|---|---|
| θ [°] | 0 |
| dc [nm] | 100 |
| Xp [nm] | 35-45 |
| df [nm] | 1000, 3000, 5000 |
| nf | 1.4-2.4 |
| da [nm] | 50 |

TABLE 6
[Blue]

| | CIE_X Theoretical Value: | | | CIE_Y Theoretical Value: | | | Luminance Theoretical Value: | | |
|---|---|---|---|---|---|---|---|---|---|
| | 0.14049 | | | 0.17856 | | | 108.413 | | |
| Refractive | Thickness [nm] | | | Thickness [nm] | | | Thickness [nm] | | |
| Index | 1000 | 3000 | 5000 | 1000 | 3000 | 5000 | 1000 | 3000 | 5000 |
| 1.4 | 0.13099 | 0.14001 | 0.13986 | 0.21696 | 0.17022 | 0.17062 | 88.439 | 94.258 | 94.423 |
| | 0.59813% | 0.83216% | 0.80677% | 1.43863% | 2.66540% | 2.54758% | 10.44340% | 8.62043% | 8.52155% |
| 1.6 | 0.13640 | 0.14018 | 0.14015 | 0.19300 | 0.17522 | 0.17551 | 94.307 | 98.208 | 98.476 |
| | 1.26283% | 0.64508% | 0.65595% | 5.63006% | 1.56401% | 1.79412% | 4.50423% | 6.15209% | 6.17120% |
| 1.8 | 0.13796 | 0.14078 | 0.14040 | 0.18078 | 0.17893 | 0.18171 | 104.031 | 101.630 | 101.574 |
| | 1.40600% | 0.54699% | 0.06623% | 5.59574% | 1.26781% | 1.56858% | 2.49628% | 4.24337% | 4.30465% |
| 2.0 | 0.14012 | 0.14110 | 0.14112 | 0.17383 | 0.18326 | 0.18496 | 108.351 | 104.360 | 104.212 |
| | 1.39365% | 0.39792% | 0.42479% | 4.18775% | 0.83712% | 3.20203% | 2.75068% | 2.58866% | 2.74723% |
| 2.2 | 0.14190 | 0.14147 | 0.14100 | 0.17173 | 0.18603 | 0.18411 | 107.816 | 107.182 | 108.412 |
| | 1.15155% | 0.44742% | 0.35630% | 1.90932% | 0.57174% | 1.33476% | 2.50298% | 3.56156% | 2.51842% |
| 2.4 | 0.14381 | 0.14169 | 0.14021 | 0.17687 | 0.18895 | 0.19282 | 107.792 | 109.739 | 112.021 |
| | 0.65973% | 0.51902% | 1.31477% | 1.40865% | 1.01768% | 1.29422% | 4.38284% | 4.73403% | 6.95396% |

TABLE 7
[Green]

| | CIE_X Theoretical Value: | | | CIE_Y Theoretical Value: | | | Luminance Theoretical Value: | | |
|---|---|---|---|---|---|---|---|---|---|
| | 0.37720 | | | 0.59918 | | | 424.765 | | |
| Refractive | Thickness [nm] | | | Thickness [nm] | | | Thickness [nm] | | |
| Index | 1000 | 3000 | 5000 | 1000 | 3000 | 5000 | 1000 | 3000 | 5000 |
| 1.4 | 0.44748 | 0.37346 | 0.37438 | 0.53204 | 0.60221 | 0.60115 | 319.026 | 319.026 | 357.611 |
| | 1.82360% | 1.01625% | 1.26383% | 1.35807% | 0.26822% | 0.36249% | 4.63972% | 4.63972% | 4.67836% |
| 1.6 | 0.35198 | 0.37763 | 0.37635 | 0.63307 | 0.59835 | 0.59969 | 427.292 | 427.292 | 380.464 |
| | 4.85796% | 0.89651% | 0.92578% | 1.74168% | 0.26466% | 0.26633% | 2.63259% | 2.63259% | 3.17546% |
| 1.8 | 0.34982 | 0.37758 | 0.37754 | 0.62778 | 0.59908 | 0.59896 | 434.230 | 434.230 | 401.476 |
| | 1.94924% | 0.74022% | 0.65656% | 0.87932% | 0.21864% | 0.19032% | 4.27442% | 4.27442% | 2.00810% |
| 2.0 | 0.38659 | 0.37821 | 0.37868 | 0.58534 | 0.59843 | 0.59813 | 406.331 | 406.331 | 419.633 |
| | 2.14950% | 0.43333% | 0.44728% | 0.87783% | 0.12418% | 0.12957% | 3.81200% | 3.81200% | 1.14063% |
| 2.2 | 0.38873 | 0.37985 | 0.37991 | 0.58586 | 0.59725 | 0.59703 | 411.567 | 411.567 | 436.075 |
| | 0.48773% | 0.63708% | 0.60997% | 0.26098% | 0.19080% | 0.18634% | 2.26550% | 2.26550% | 2.10856% |
| 2.4 | 0.38446 | 0.38078 | 0.38136 | 0.59495 | 0.59665 | 0.59537 | 449.022 | 449.022 | 448.737 |
| | 1.34315% | 0.78413% | 1.06608% | 0.55220% | 0.24163% | 0.29968% | 4.67652% | 4.67652% | 3.39995% |

TABLE 8
[Red]

| | CIE_X Theoretical Value: | | | CIE_Y Theoretical Value: | | | Luminance Theoretical Value: | | |
|---|---|---|---|---|---|---|---|---|---|
| | 0.67627 | | | 0.32349 | | | 105.604 | | |
| Refractive | Thickness [nm] | | | Thickness [nm] | | | Thickness [nm] | | |
| Index | 1000 | 3000 | 5000 | 1000 | 3000 | 5000 | 1000 | 3000 | 5000 |
| 1.4 | 0.61971 | 0.67465 | 0.67634 | 0.37979 | 0.32509 | 0.32344 | 57.092 | 85.975 | 87.422 |
| | 0.40644% | 0.10409% | 0.09497% | 0.65825% | 0.21463% | 0.19653% | 18.47661% | 0.76080% | 0.61061% |
| 1.6 | 0.70016 | 0.67590 | 0.67637 | 0.29970 | 0.32385 | 0.32338 | 86.788 | 93.481 | 94.224 |
| | 0.48686% | 0.07675% | 0.06495% | 1.13068% | 0.15894% | 0.13318% | 12.60823% | 0.35478% | 0.37401% |
| 1.8 | 0.67835 | 0.67635 | 0.67634 | 0.32142 | 0.32342 | 0.32341 | 127.268 | 99.956 | 100.149 |
| | 0.95012% | 0.04232% | 0.03875% | 1.99548% | 0.08776% | 0.08120% | 2.70559% | 0.16830% | 0.18575% |
| 2.0 | 0.65152 | 0.67642 | 0.67636 | 0.34811 | 0.32334 | 0.32341 | 85.489 | 105.536 | 105.438 |
| | 0.39881% | 0.02671% | 0.02539% | 0.74233% | 0.05494% | 0.05166% | 5.17028% | 0.15263% | 0.13909% |
| 2.2 | 0.68990 | 0.67642 | 0.67632 | 0.30994 | 0.32334 | 0.32345 | 111.882 | 110.448 | 110.393 |
| | 0.27373% | 0.04979% | 0.04886% | 0.60598% | 0.10237% | 0.10181% | 5.33308% | 0.24299% | 0.22546% |
| 2.4 | 0.67626 | 0.67642 | 0.67640 | 0.32351 | 0.32334 | 0.32336 | 125.847 | 114.879 | 114.992 |
| | 0.64345% | 0.06834% | 0.07191% | 1.33660% | 0.14052% | 0.14985% | 2.04373% | 0.32465% | 0.40670% |

In all the colors, when the thickness df was set to 3,000 nm and 5,000 nm, the deviations from the ideal value of the average were smaller than that when the thickness df was set to 1,000 nm. When the refractive index n fell within the range of 1.8 to 2.2, the deviations from the ideal value of the average were minimum for the refractive index of 2.0. In this case, refractive index n=1.0 to 2.2 is almost equal to the refractive index (1.9 to 2.1) of ITO as a transparent electrode material. If the refractive index of the thick layer F is equal to that of ITO that forms the transparent anode electrode 1, the effects of reflection and refraction between the transparent anode electrode 1 (ITO) and the thick layer F can be neglected. It is therefore expected that the interference effects of the optical paths R11 to R13 shown in FIG. 16 are eliminated, and the shift with a change in film thickness is minimized.

According to the calculation results shown in Tables 6 to 8, the thick layer F is preferably a film with high transparency because the refractive index n and the thickness df need to be approximately 2.0 and 3,000 nm or more, respectively, and the film needs to have a light transmission characteristic. It is practically very difficult to form a thick layer that satisfies the above conditions.

Examples of transparent films that are used in a general thin-film transistor (TFT) manufacturing process and have refractive indexes of approximately 2.0 are transparent oxide metal films such as an ITO film and silicon nitride films. A process in vacuum, e.g., the PECVD (Plasma Enhanced Chemical Vapor Deposition) method or the sputtering method is indispensable to the formation of thick layers using these films. When a thick film having a thickness of 1,000 nm or more is to be formed by using the above process, the throughput may deteriorate or the film may crack due to film stress.

Using, as the thick layer F, an organic film having a thermosetting property, e.g., an acrylic-based resin, epoxy-based resin, or polyimide-based resin film allows the use of a coating method such as the spin coating method. This process using such an organic film is therefore much easier to form a thick film of a thickness of 1,000 nm or more than a process using an inorganic film such as an ITO or SiN film. However, since the refractive indexes n of these organic films are approximately 1.6, the spectrum shift suppressing effect based on film thickness cannot be maximized.

When the above thick layer F is to be formed in an organic EL element having a light emission structure based on the top emission scheme, it is difficult from a process viewpoint to use inorganic films such as ITO and SiN films.

Based on the above description, a film thickness that could maximize the spectrum shift suppressing effect was obtained by calculating a change in the effectiveness of the shift suppressing effect based on the thickness df with the use of an organic film having refractive index n=approximately 1.6 as the thick layer F.

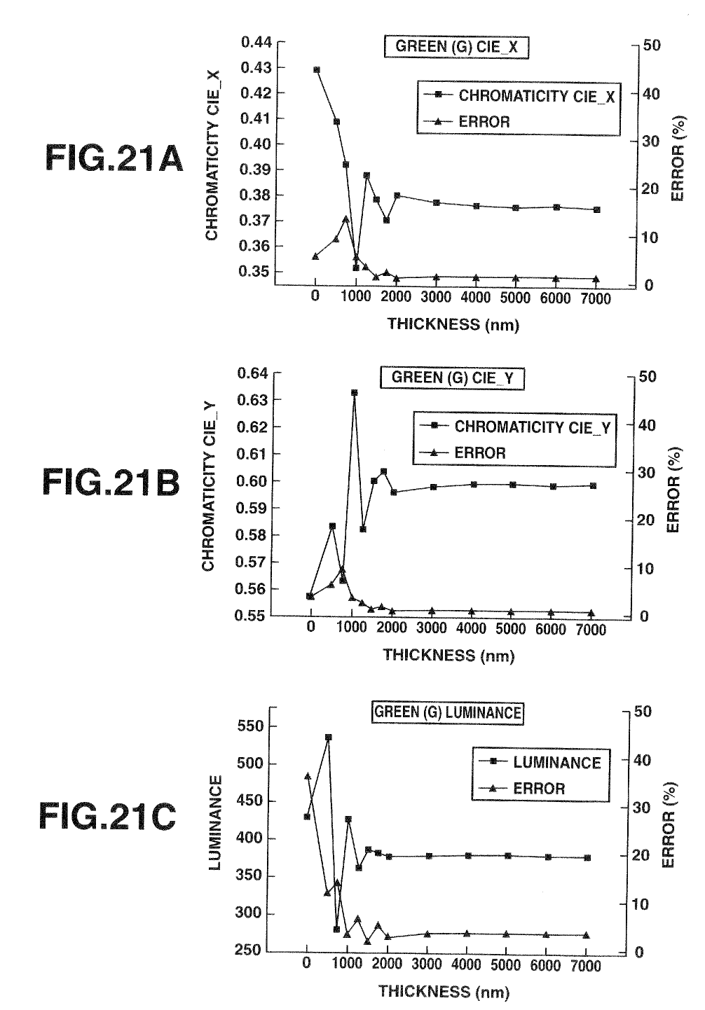

FIGS. 21A, 21B, and 21C are graphs showing calculation results on the relationships between the thickness of a thick layer, the x-coordinate of the chromaticity CIE(x, y), the y-coordinate of the chromaticity CIE(x, y), and luminance in the interference calculation model (green (G)) according to this embodiment.

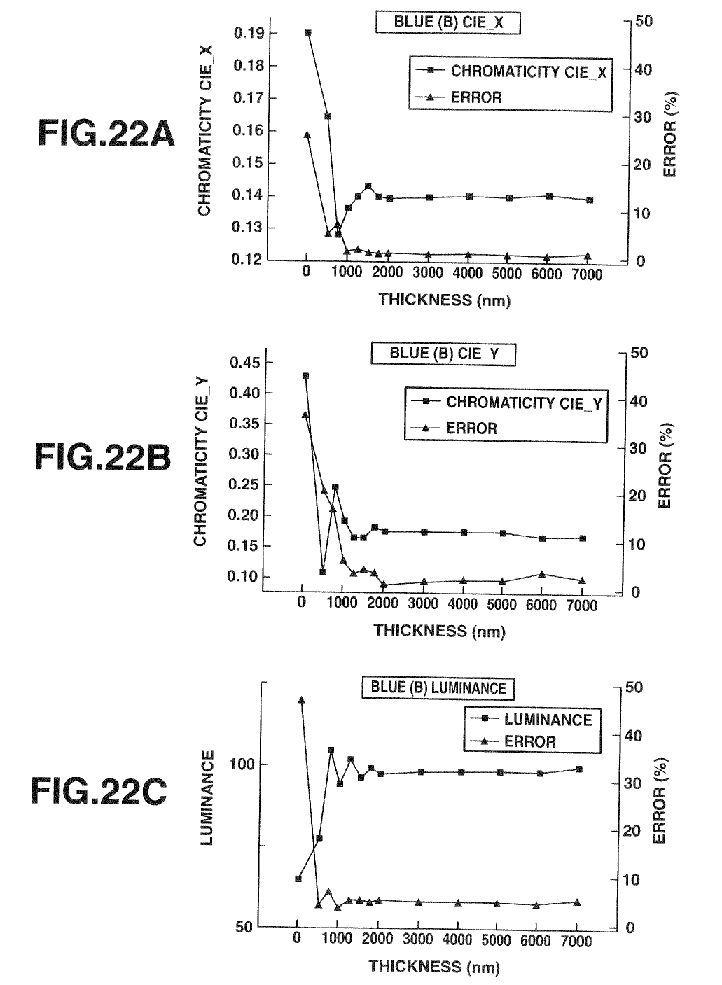

FIGS. 22A, 22B, and 22C are graphs showing calculation results on the relationships between the thickness of a thick layer, the x-coordinate of the chromaticity CIE(x, y), the y-coordinate of the chromaticity CIE(x, y), and luminance in the interference calculation model (blue (B)) according to this embodiment.

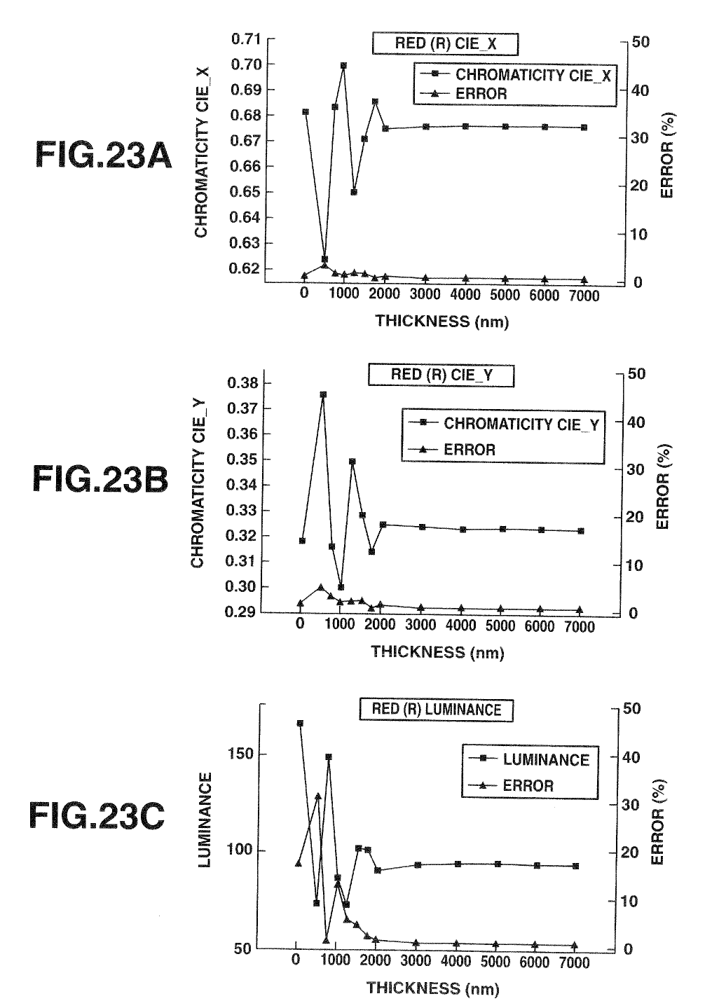

FIGS. 23A, 23B, and 23C are graphs showing calculation results on the relationships between the thickness of a thick layer, the x-coordinate of the chromaticity CIE(x, y), the y-coordinate of the chromaticity CIE(x, y), and luminance in the interference calculation model (red (R)) according to this embodiment.

In this case, chromaticities (X, Y), average values of luminances, and errors calculated by using the parameters shown in Table 9 for each color of R, G, and B are plotted with respect to the thickness df of the thick layer F.

TABLE 9

| | Blue (B) | Green (G) | Red (R) |
|---|---|---|---|
| Xqmin [nm] | 60 | 55 | 60 |
| Xqmax [nm] | 80 | 75 | 80 |

| | |
|---|---|
| θ [°] | 0 |
| dc [nm] | 100 |
| Xp [nm] | 35-45 |
| df [nm] | 1000-7000 |
| nf | Equal to nf of ITO |
| da [nm] | 50 |

Referring to FIGS. 21A, 21B, 21C, 22A, 22B, 22C, 23A, 23B, and 23C, when the thickness df of the thick layer F is 0, i.e., no thick layer F is used, the error between the chromaticity (X, Y) and luminance in the case of green (G) and blue (B) is large, and the average is shifted from the ideal value. As the thickness df increases, the error decreases. When df=2000 nm or more, the average converges to the ideal value. In the case of red (R) as well, when thickness df=2000 nm or more, a similar tendency appears. That is, it was found that setting the thickness df of the thick layer F to 2,000 nm or more for all the colors R, G, and B made it possible to sufficiently suppress the shift due to the thickness of the electroluminescent layer 2. Even if the thickness df of the thick layer F is set to 7,000 nm or more, the error does not greatly decrease. In addition, this makes it difficult from a process viewpoint to pattern the film (thick layer). For this reason, the thickness df of the thick layer F that can be applied to this embodiment preferably falls within the range of 2,000 nm to 7,000 nm. In addition, when changes in chromaticity and luminance with changes in viewing angle were inspected when the thick layer F was inserted, it was found as shown in Table 10 that the shifts in chromaticity and luminance with changes in viewing angles were suppressed as compared with the case in which the thick layer F was not inserted.

TABLE 10

| | | Viewing angle θ[°] | | | | | | |
|---|---|---|---|---|---|---|---|---|
| | | 0 | 15 | 30 | 45 | 60 | 75 | 90 |
| Without Thick | Chromaticity | 0.538605 | 0.541221 | 0.54819 | 0.5575402 | 0.566915 | 0.5737819 | 0.576274 |
| Layer | CIE_X | | | | | | | |
| | Chromaticity | 0.451528 | 0.448517 | 0.440484 | 0.4296739 | 0.418741 | 0.4106141 | 0.407629 |
| | CIE_Y | | | | | | | |
| | Luminance | 290 | 305.5681 | 350.6611 | 416.01895 | 482.4947 | 528.18528 | 543.4382 |
| Thick Layer with | Chromaticity | 0.596096 | 0.599611 | 0.608206 | 0.5943508 | 0.606125 | 0.6034725 | 0.597136 |
| Thickness of | CIE_X | | | | | | | |
| 2,000 nm and | Chromaticity | 0.379713 | 0.376868 | 0.367953 | 0.3802122 | 0.370876 | 0.3710584 | 0.376923 |
| Refractive Index | CIE_Y | | | | | | | |
| of 1.6 | Luminance | 384.2308 | 387.9807 | 392.0542 | 361.16495 | 369.178 | 351.06147 | 339.4033 |

In this embodiment, therefore, a display panel provided with display pixels each having an organic EL element having a light emission structure based on the top emission scheme can generate many interference peaks throughout a wide range by interposing a light irradiation control insulating film (thick layer) having a refractive index (approximately 1.6) almost equal to that of a pixel electrode, a thickness of 2,000 nm or more, and a light transmission characteristic between an pixel electrode (transparent anode electrode) and a fiat reflecting layer (reflecting metal) that constitute an organic EL element. This makes it possible to greatly suppress variations in emission intensity and chromaticity due to the thickness of an organic EL layer (electroluminescent layer) and also reduce the viewing angle dependence, thereby implementing a display apparatus with excellent visibility without any image blurring or the like.

Note that the above function/effect inspection concerning the relationship between the thickness df of the thick layer F and the spectrum shift suppressing effect, which is a characteristic feature of this embodiment, has indicated on the basis of the calculation results shown in FIGS. 21A, 21B, 21C, 22A, 22B, 22C, 23A, 23B, and 23C that setting the thickness df of the thick layer F to 2,000 nm or more for all the colors P, G, and B can sufficiently suppress the shift due to the thickness of the electroluminescent layer 2. More specifically, since different characteristics (calculation results) are observed for the respective colors R, G, and B (emission colors), the thickness df of the thick layer F can be properly set to different values for the respective light-emitting elements (organic EL elements) of the respective colors. This can obtain a proper spectrum shift suppressing effect in accordance with the characteristic for each color as compared with the case in which the thickness df of the thick layer F is set to the same thickness (uniform thickness) of 2,000 nm or more.

### SECOND EMBODIMENT

(Device Structure of Display Pixel)

The second embodiment of the display apparatus and its manufacturing method according to the present invention will be described next.

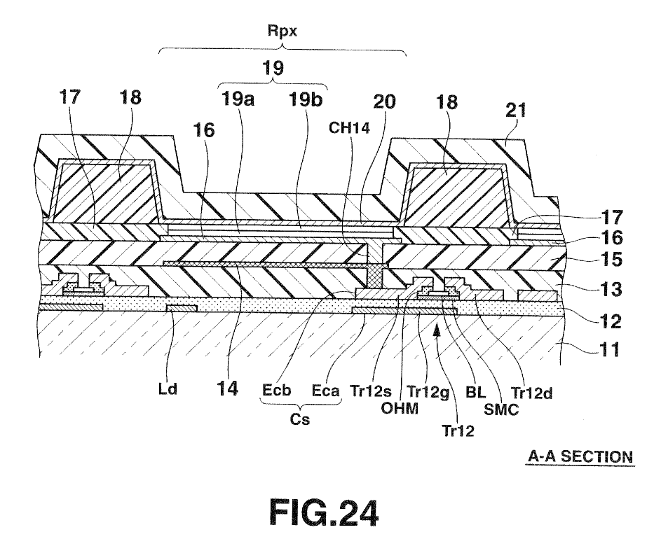

FIG. 24 is a schematic sectional view showing the panel structure of the display apparatus according to the second embodiment. A description of components similar to those of the first embodiment will be omitted or simplified.

The first embodiment described above (see FIGS. 4A and 4B) has the panel structure in which the flat reflecting layer 14 provided below the pixel electrode 16 of the organic EL element OLED is formed electrically independently between the protective insulating film 13 and the light irradiation control insulating film 15. The second embodiment has a panel structure in which the flat reflecting layer 14 is electrically connected to the pixel electrode 16 and the source electrode Tr12s of the transistor Tr12 (or the electrode Ecb on the other side of the capacitor Cs).

More specifically, as shown in FIG. 24, in the display panel according to this embodiment, a flat reflecting layer 14 provided on a protective insulating film 13 formed to cover the respective circuit elements (transistors Tr11 and Tr12, a capacitor Cs, and the like) of each driving circuit DC and interconnection layers (a data line Ld, a selection line Ls, a power supply voltage line Lv, and the like) formed on one surface of an insulating substrate 11 has a planar shape corresponding to a pixel formation area Rpx (an organic EL element OLED formation area) and is electrically connected to a source electrode Tr12s of a transistor Tr12 (an electrode Eca on the other side of the capacitor Cs) via a contact hole CH14 provided in the protective insulating film 13.

A pixel electrode 16 provided on a light irradiation control insulating film 15 covering the flat reflecting layer 14 extends to an area corresponding to the flat reflecting layer 14, and is electrically connected to the source electrode Tr12s of the transistor Tr12 via the flat reflecting layer 14 in the contact hole CH14 provided in the light irradiation control insulating film 15. That is, the source electrode Tr12s of the transistor Tr12 (the electrode Eca on the other side of the capacitor Cs), the flat reflecting layer 14, and the pixel electrode 16 are always kept at the same potential in the display driving operation of a display pixel PIX.

The display apparatus according to this embodiment has the following effect in addition to the functions and effects of the first embodiment described above. Since the source electrode Tr12s of the transistor Tr12 (the electrode Eca on the other side of the capacitor Cs), the fiat reflecting layer 14, and the pixel electrode 16 are set at the same potential, no capacitance is formed between the flat reflecting layer 14 and the source electrode Tr12s of the transistor Tr12 that face each other through the protective insulating film 13 and between the flat reflecting layer 14 and the pixel electrode 16 that face each other through the light irradiation control insulating film 15. This allows suppression of a delay in write operation and the voltage fluctuation of a tone signal at the time of the display driving of the display pixel PIX, and allows the display pixel PIX to emit light at a more proper luminance level corresponding to display data.

<Method of Manufacturing Display Apparatus>

A method of manufacturing the above display apparatus (display panel) will be described next.

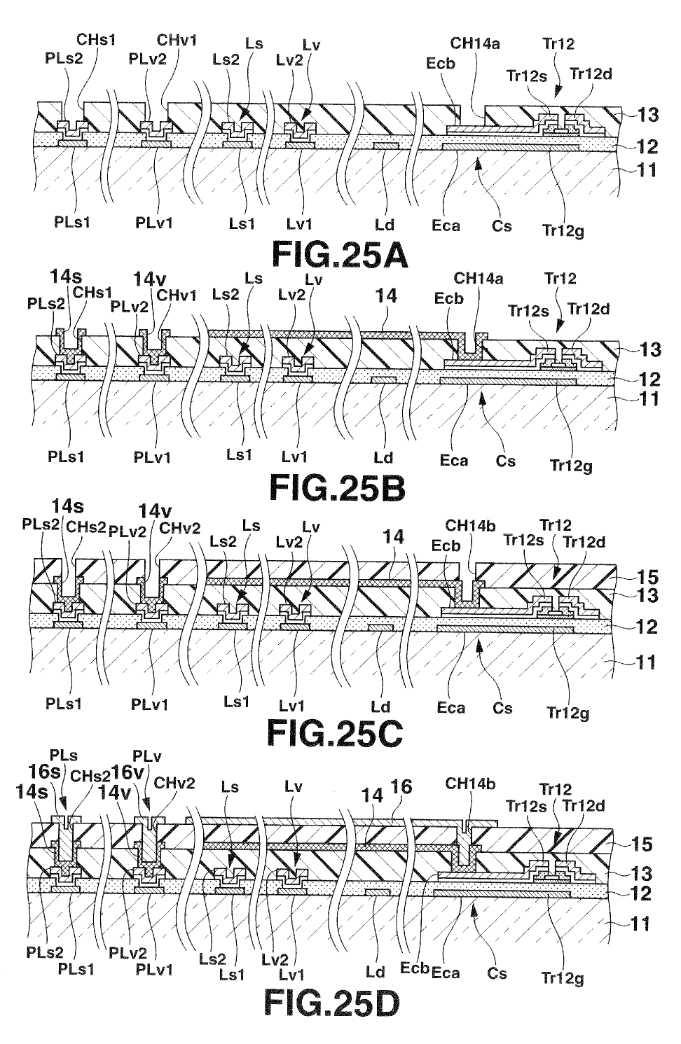

FIGS. 25A, 25B, 25C, and 25D are sectional views showing an example of a method of manufacturing a display apparatus (display panel) according to this embodiment. A description of steps similar to those in the manufacturing method according to the first embodiment will be simplified. Since terminal pads PLs and PLv of the selection line Ls and power supply voltage line Lv that are formed simultaneously with the respective circuit elements of a pixel driving circuit and interconnection layers are the same as those in the first embodiment, a repetitive description will be omitted.

According to the method of manufacturing the display apparatus according to this embodiment, as in the manufacturing method according to the first embodiment, first of all, the transistors Tr11 and Tr12 and capacitor Cs of the pixel driving circuit DC, and interconnection layers such as the data line Ld, the selection line Ls, and the power supply voltage line Lv are formed on one surface of the insulating substrate 11, as shown in FIG. 6A, and the protective insulating film (planarization film) 13 is formed to cover the resultant structure, and the contact hole (first opening portion) CH14a is formed to expose at least the source electrode Tr12s of the transistor Tr12 (the electrode Ecb on the other side of the capacitor Cs), as shown in FIG. 25A.

A thin metal film having a light reflection characteristic that is formed on the protective insulating film 13, including the contact hole CH14a, by using the sputtering method or the like is patterned to form the flat reflecting layer 14 that has a planar shape corresponding to each pixel formation area Rpx (an organic EL element OLED formation area) and is electrically connected to the source electrode Tr12s of the transistor Tr12 in the contact hole CH14a, as shown in FIG. 25B.

As shown in FIG. 25C, the light irradiation control insulating film 15 having, for example, a thickness of 2,000 nm or more is formed to cover the entire area of one surface of the insulating substrate 11 including the flat reflecting layer 14, and the light irradiation control insulating film 15 is etched to form a contact hole (second opening portion) CH14b, in the area in which the contact hole CH14a is formed, in which the upper surface of the flat reflecting layer 14 is exposed.

Subsequently, a conductive oxide metal layer made of ITO is formed thin on the entire area of one surface of the insulating substrate 11 including the contact hole CH14b, and the conductive oxide metal layer is patterned to form the pixel electrode 16 having a light transmission characteristic that is electrically connected to the flat reflecting layer 14 in the contact hole CH14b and extends onto the light irradiation control insulating film 15 in an area corresponding to the pixel formation area Rpx (i.e., an area corresponding to the flat reflecting layer 14), as shown in FIG. 25D.

As shown in FIGS. 7B and 7C, an underlying insulating film 17 is then formed, which covers the boundary areas between the adjacent display pixels PIX (the areas between the pixel electrodes 16) and has opening portion in which the upper surfaces of the pixel electrodes 16 are exposed. Banks 18 are formed on the underlying insulating film 17 so as to continuously protrude. With this process, the pixel formation area Rpx of each display pixel PIX (the formation area of an organic EL layer 19 of each organic EL element OLED) is defined.

Subsequently, as shown in FIGS. 8A and 8B, the organic EL layer 19 is formed by sequentially stacking a hole transport layer 19a and an electron transport luminescent layer 19b on the pixel electrode 16 in each pixel formation area Rpx. A common opposed electrode 20 is formed to face at least the pixel electrodes 16 of the display pixels PIX, thereby completing the organic EL element OLED of each display pixel PIX (pixel formation area Rpx). A sealing layer 21 serving as a protective insulating film is formed on the entire area of one surface of insulating substrate 11 to complete the display panel 10 having a sectional structure like that shown in FIG. 24.

As described above, in the method of manufacturing the display apparatus according to this embodiment, when a flat reflecting layer is formed on the protective insulating film 13 on the insulating substrate on which the respective circuit elements and interconnection layers of each pixel driving circuit are formed, the flat reflecting layer 4 is formed so as to be connected to the source electrode Tr12s of the transistor Tr12 via the contact hole CH14a provided in the protective insulating film 13 and cover the contact hole CH14. Therefore, when the flat reflecting layer is to be formed by patterning the reflecting metal layer and the contact hole CH14b is formed by patterning the light irradiation control insulating film 15, damage to the source electrode Tr12s of the transistor Tr12 (the dissolution of a source metal by an etchant) can be reduced, and the source electrode Tr12s and the pixel electrode 16 can be electrically connected to each other in a proper connected state.

Each embodiment described above has exemplified the case in which the banks that are made of the resin material and continuously protrude from the surface of the substrate are formed to define the pixel formation areas Rpx of the display pixels PIX. However, the present invention is not limited to this. For example, at least the surfaces of the banks are formed by conductive thin films, and the opposed electrode 20 commonly formed for the display pixels PIX are electrically connected to the banks. The resultant structure can be used as a common power supply line (e.g., a cathode line) for applying the reference voltage Vcom.

In addition, each embodiment described above has exemplified the circuit arrangement using the two n-channel transistors (i.e., the thin-film transistors having the single channel polarity) Tr11 and Tr12 as the pixel driving circuit DC provided for the display pixel PIX (the color pixels PXr, PXg, and PXb) of the display panel 10, as shown in FIG. 2. However, the display apparatus according to the present invention is not limited to this. This apparatus can use another circuit arrangement using three or more transistors, or using only p-channel transistors, or using transistors having both channel polarities, i.e., n- and p-channel transistors.

As in this embodiment, when only n-channel transistors are to be used, transistors having stable operation characteristics can be easily manufactured by using the amorphous silicon semiconductor manufacturing technique that is an already established manufacturing technique. In addition, this method can implement pixel driving circuits in which variations in the emission characteristics of the above display pixels are suppressed.

Furthermore, each embodiment described above has exemplified the case in which the voltage designation (voltage tone control) type pixel driving circuit that sets the luminance level of the organic EL element OLED by supplying a tone signal (tone voltage) having a voltage corresponding to display data is used for each display pixel. However, the display apparatus according to the present invention is not limited to this. A current designation (current tone control) type pixel driving circuit that sets the luminance level of the organic EL element OLED by supplying a tone current corresponding to display data can be applied to each display pixel.

Moreover, each embodiment described above has exemplified the device structure in which the organic EL layer 19 serving as a light-emitting function layer is formed by stacking the hole transport layer 19a and the electron transport luminescent layer 19b. However, the present invention is not limited to this. Each embodiment can use a device structure including a hole transport luminescent layer and an electron transport layer, a device structure comprising only a single layer serving both as a hole transport luminescent layer and an electron transport luminescent layer, a device structure having a three-layer structure comprising a hole transport layer, a luminescent layer, and an electron transport layer, or a device structure having a multilayer structure including another interposition layer such as an interlayer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A display apparatus comprising:
a light-emitting function layer including at least one layer;
a first electrode that has a transmission characteristic with respect to at least light having a wavelength that is in part of a wavelength range of light emitted from the light-emitting function layer;
a second electrode that is provided to face the first electrode through the light-emitting function layer and has a transmission characteristic with respect to at least the light having the wavelength that is in part of the wavelength range of the light emitted from the light-emitting function layer;
a flat reflecting layer that has a reflection characteristic with respect to at least the light having the wavelength that is in part of the wavelength range of the light emitted from the light-emitting function layer; and
a flat insulating film that is provided between the flat reflecting layer and the first electrode and has a transmission characteristic with respect to at least the light having the wavelength that is in part of the wavelength range of the light emitted from the light-emitting function layer.

2. An apparatus according to claim 1, wherein the flat insulating film has a refractive index substantially equal to that of the first electrode.

3. An apparatus according to claim 1, wherein the first electrode includes a conductive oxide metal layer, and the flat insulating film includes an organic film.

4. An apparatus according to claim 1, wherein the flat insulating film has a refractive index of approximately 1.6, and a thickness of not less than 2,000 nm.

5. An apparatus according to claim 1, wherein
the light-emitting function layer includes luminescent layers of different emission colors for the respective pixels, and
the flat insulating film has different thicknesses in accordance with the different emission color luminescent layers.

6. An apparatus according to claim 1, further comprising a pixel driving circuit that is connected to the first electrode and supplies an emission driving current.

7. An apparatus according to claim 1, further comprising
a pixel driving circuit that supplies an emission driving current, and
a protective insulating film that covers the pixel driving circuit, and wherein
the first electrode is connected to the pixel driving circuit through an opening portion extending through the flat insulating film and the protective insulating film.

8. An apparatus according to claim 1, further comprising a pixel driving circuit that supplies an emission driving current, and wherein
the flat reflecting layer is electrically connected to the pixel driving circuit and the first electrode is electrically connected to the flat reflecting layer.

9. An apparatus according to claim 1, further comprising
a pixel driving circuit that supplies an emission driving current, and
a protective insulating film that covers the pixel driving circuit, and wherein
the flat reflecting layer is connected to the pixel driving circuit through a first opening portion provided in the protective insulating film, and
the first electrode is electrically connected to the flat reflecting layer through a second opening portion provided in the flat insulating film.

10. An apparatus according to claim 1, further comprising a pixel driving circuit that supplies an emission driving current and includes an electrode and an interconnection layer, and wherein
at least one of the electrode and the interconnection layer of the pixel driving circuit two-dimensionally overlaps the first electrode through the flat insulating film.

11. An apparatus according to claim 1, wherein the light-emitting function layer includes an organic EL layer.

12. An apparatus according to claim 1, wherein the light-emitting function layer includes a polymer-based organic material.

13. A method of manufacturing a display apparatus including a light-emitting function layer, the method comprising steps of:
forming a flat reflecting layer having a reflection characteristic with respect to at least light having a wavelength that is in part of a wavelength range of light emitted from the light-emitting function layer;
forming, on the flat reflecting layer, a flat insulating film that has a transmission characteristic with respect to at least the light having the wavelength that is in part of the wavelength range of the light emitted from the light-emitting function layer;
forming, on the flat insulating film, a first electrode that has a transmission characteristic with respect to at least the light having the wavelength that is in part of the wavelength range of the light emitted from the light-emitting function layer;
forming the light-emitting function layer on the first electrode; and
forming, on the light-emitting function layer, a second electrode that has a transmission characteristic with respect to at least the light having the wavelength that is in part of the wavelength range of the light emitted from the light-emitting function layer.

14. A method of manufacturing a display apparatus including a light-emitting function layer, the method comprising steps of:
forming a protective insulating film that has a first opening portion on a pixel driving circuit;
forming, on the protective insulating film and the first opening portion, a flat reflecting layer that has a reflection characteristic with respect to at least light having a wavelength that is in part of a wavelength range of light emitted from the light-emitting function layer;
forming a flat insulating film that has a second opening portion exposing a portion of the flat reflecting layer and has a transmission characteristic with respect to at least the light having the wavelength that is in part of the wavelength range of the light emitted from the light-emitting function layer covering the other portion of the flat reflecting layer;
forming, on the flat insulating film and the second opening portion, a first electrode that has a transmission characteristic with respect to at least the light having the wavelength that is in part of the wavelength range of the light emitted from the light-emitting function layer;
forming the light-emitting function layer on the first electrode; and
forming, on the light-emitting function layer, a second electrode that has a transmission characteristic with respect to at least the light having the wavelength that is in part of the wavelength range of the light emitted from the light-emitting function layer.

15. A method according to claim 13, wherein the flat insulating film has a refractive index substantially equal to that of the first electrode.

16. A method according to claim 13, wherein the flat insulating film has a refractive index of approximately 1.6, and a thickness of not less than 2,000 nm.

17. A method according to claim 13, wherein
the light-emitting function layer includes luminescent layers of different emission colors for the respective pixels, and
the flat insulating film has different thicknesses in accordance with the different emission color luminescent layers.
